(19) United States
(12) Patent Application Publication
(10) Pub. No.: US 2016/0197998 A1
(43) Pub. Date: Jul. 7, 2016

(54) MONITORING SYSTEM

(71) Applicant: XEROS LIMITED, Rotherham (GB)

(72) Inventor: Mark A. Carleo, Topsfield, MA (US)

(21) Appl. No.: 14/588,510

(22) Filed: Jan. 2, 2015

(51) Int. Cl. H04L 29/08; G01R 31/327

(52) U.S. Cl. CPC H04L 67/12; G01R 31/3278; H04L 67/125

(57) ABSTRACT

A data acquisition device for monitoring an appliance, the device being removably attachable to the appliance and including one or more sensors, each sensor being removably attachable to a component of the appliance for sensing a state of that component, an interface configured, when the apparatus is attached to the appliance, to receive, process and transmit data indicative of the operation of the appliance, the interface including: one or more sensor inputs, each configured to receive a signal from a corresponding one of the one or more sensors, a processor configured to process the signals received from the one or more sensors and generate a data packet containing data indicative of the operation of the appliance based on the received signals, and a communications module configured to transmit the data packet generated by the processor to a local gateway or remote server.

### BACKGROUND OF THE INVENTION

1. Field of the Invention

The present invention relates to a monitoring system for monitoring an appliance. More specifically, the invention is concerned with an appliance monitoring and reporting system, a data acquisition device for monitoring an appliance and a relay state sensor.

2. Description of Related Art

It is known to monitor the operation of appliances for a variety of purposes.

Appliances, including washing machines, dryers, dishwashers and the like, use utilities (including products), such as chemicals, water, gas and electricity during operation. Systems are known which monitor the utility usage of an appliance over time. These systems are typically used to measure the efficiency of an appliance and for the generation of management reports, when usage data is combined with the costs of the utilities.

One such system is described in U.S. Pat. No. 6,377,868, in the name of Gardner Jr. and assigned to Ecolab, Inc. The patent, entitled “Data Processing System For Managing Chemical Product Usage”, is one of a family of patents in the same name, describe a system for monitoring chemical product usage by an automated chemical product dispenser of the kind which is typically found connected to one or more washing machines in a commercial laundry. The system comprises a monitor module, typically the controller of the dispenser, which records chemical usage data of the dispenser over time and forwards the data to a central server for display.

Another such system is described in a US patent application with the publication number US 2013/0135116, in the name of Garbe. The patent application, entitled “Method For Processing Data In A Domestic Appliance, Domestic Appliance And System Having A Domestic Appliance And At Least One External Unit”, describes a washing machine having an integrated appliance data determination unit coupled to a control unit of the washing machine. The appliance data determination unit communicates with the control unit of the washing machine to receive appliance data, including cycles of operation, the time at which the cycles of operation are performed, and energy consumption data of the appliance. The data is then incorporated into a user profile either by the appliance data determination unit itself or by an external device. The user profile comprises a record of operation and usage data for the appliance over time.

Other systems are known to monitor abnormal events during operation of an appliance. One such system is described in US patent number U.S. Pat. No. 6,778,868, in the name of Imamura. The patent, entitled “Remote Control Of Laundry Appliance”, describes a washing machine having a laundry appliance control section, which is adapted to detect abnormal conditions of operation of the washing machine and to send error codes indicative of the abnormal condition to a server for analysis.

The above-described monitoring systems are either integrated into a controller of an appliance or are configured to be connected to and communicate with the controller of an appliance. These systems must therefore be specifically programmed to interact with the controller of a particular appliance. Accordingly, these systems must be pre-installed during manufacture of the appliance and supplied as integral components for each appliance.

In some situations, it is desirable to monitor utility usage of an appliance which is not pre-installed with a bespoke system for doing so. For example, a commercial laundry may operate a suite of washing machines and dryers which have no utility monitoring capability. Such appliances may have served the owner well for many years, in which case the owner would be very reluctant to replace them with more sophisticated machines. Although the laundry owner could utilize the chemical product dispenser described in U.S. Pat. No. 6,377,868 to Ecolab, Inc., to provide some monitoring of the chemical usage in the laundry, this is not an optimal solution. Firstly, the dispenser would not provide the owner with information on utilities other than chemicals; and secondly a dispenser serving a plurality of washing machines would not be able to discern utility usage of each machine.

It would therefore be desirable for an appliance vendor to be able to provide prospective customers such as the laundry owner with a tool that can monitor the prospective customer's existing appliances and utility usage.

### BRIEF SUMMARY OF THE INVENTION

According to the present invention there is provided a monitoring system as described in the accompanying claims.

According to a first aspect of the invention there is provided a data acquisition device for monitoring an appliance, the device being removably attachable to the appliance and comprising:
one or more sensors, each sensor being removably attachable to a component of the appliance for sensing a state of that component; and
an interface configured, when the apparatus is attached to the appliance, to receive, process and transmit data indicative of the operation of the appliance, the interface including:
   one or more sensor inputs, each configured to receive a signal from a corresponding one of the one or more sensors;
   a processor configured to process the signals received from the one or more sensors and generate a data packet containing data indicative of the operation of the appliance based on the received signals; and
   a communications module configured to transmit the data packet generated by the processor to a local gateway or remote server.

The removability of the device from an appliance enables the device to be installed on and removed from an appliance without significant structural alteration of the appliance. Moreover, the capacity of the device to transmit data indicative of the operation of the device by sensing a state of a component of the device means that the monitoring device is entirely passive with respect to the appliance, and can be retrofit onto any existing appliance that do not have any capacity for monitoring utility usage. The one or more sensors enable the device to monitor one or more components of the appliance whilst maintaining electrical isolation of the device from the appliance. The interface enables the device to receive and process the data from the one or more sensors and to transmit the received data to another device.

Optionally, the interface can include one or more appliance inputs, each configured to receive a signal generated by the appliance, and wherein the processor is further configured to process the signals generated by the appliance. The signal generated by the appliance can be a utility supply signal for controlling the supply of a utility from a utility source separate from the appliance. In particular, the appliance can be a washing machine, the utility source can be a chemical dispenser, and the utility supply signal can be a chemical pump signal for controlling the supply of chemicals from the chemical dispenser. Where the appliance is a washing machine, the chemical pump signal is one of a formula select signal and a formula reset signal.

The signals which the data acquisition device senses or receives from the appliance may be operating signals of the appliance; that is, signals which in use cause the appliance (or an accessory to which the appliance is attached) to carry out a function of operation. Operating signals contrast with information signals (for example), which merely provide information about how the machine is operating, and do not themselves cause the appliance (or an accessory to which the appliance is attached) to carry out a function of operation. It is also envisaged that the system can determine faults in the appliance from these signals.

Thus, systems according to the present invention are able to provide an existing appliance which itself has no utility monitoring capacity with a system for doing so, without significant modification of the appliance. In particular, no modification of or communication with the control system of the existing appliance is needed; the systems according to the present invention will work based on operating signals that can be sensed or received comparatively easily.

Alternatively or additionally, the interface can further include one or more utility meter inputs, each configured to receive a signal generated by a utility meter, and wherein the processor is further configured to process the signals generated by the utility meter. The utility meter can be a water meter, wherein the signal generated by the water meter is indicative of the volume of cold water and/or hot water to the appliance. The utility meter can also be an electricity meter, wherein the signal generated by the electricity meter is indicative of the electrical energy delivered to the appliance.

It is envisaged that the one or more sensors can include one or more voltage sensors, and the components of the appliance include one or more signal cables configured to pass a signal generated either by the appliance or by a utility meter. The one or more the voltage sensors can include one or more split core or solid core current transformers, each disposed in a housing configured to surround the respective signal cable of the one or more signal cables.

It is also envisaged that the one or more sensors can include one or more magnetic field sensors, and the components of the appliance include one or more relays configured to control the operation of the appliance, each relay having an active state and an inactive state. Optionally, each of the one or more magnetic field sensors can be attached to or embedded within a relay housing sized and shaped for removable attachment to the respective relay of the one or more relays. The one or more relays can include one or more of:
a relay, the state of which is indicative of the start of a cycle of operation of the appliance;
a relay, the state of which is indicative of the end of a cycle of operation of the appliance;
a relay, the state of which is indicative of a call for the supply of a utility from a utility source separate from the appliance, preferably a call for the supply of chemicals from a chemical dispenser;
a relay, the state of which is indicative of the door lock status of the appliance;
a relay, the state of which is indicative of the alarm status of the appliance;
a relay, the state of which is indicative of the lint filter lock status of the appliance; and
a relay, the state of which is indicative of the drain input status of the appliance.

Optionally, the interface can further comprise a memory, wherein the processor is further configured to cause the memory to store data pertaining to the received signals for a period of time prior to generating the data packet. Preferably, if the appliance is configured to operate according to at least one operating cycle, the processor is configured to generate the data packet upon determination that the appliance has reached the end of an operating cycle.

In accordance with a second embodiment of the application there is provided a relay state sensor device removably attachable to a substantially cuboid-shaped relay for sensing the state of the relay, the sensor device comprising:
a relay housing sized and shaped for removable attachment to the relay;
a magnetic field sensor attached to or embedded within the housing; and
a signal cable electrically coupled at one end to the magnetic field sensor and extending from the housing.

The relay state sensor device of this invention is particularly easy to install compared with conventional techniques, and yet provides reliable sensing of the state of the relay.

It is envisaged that the relay housing can comprise a roof with opposing first and second planar surfaces, and at least two opposing walls depending from the first planar surface of the roof, wherein in use, the relay contacts the at least two opposing walls and the first planar surface of the roof. In this case, the magnetic field sensor can be attached to or embedded within the second planar surface and the signal cable can extend from the second planar surface.

Optionally, the relay housing can comprise four walls depending from the first planar surface of the roof. The four walls may be unconnected from each other or they may be connected together. The relay housing can form an open cavity for receiving at least part of a component to be monitored. The relay housing can be sized and shaped for attachment to the relay with an interference fit and alternatively or additionally, the relay housing can be sized and shaped for attachment to the relay with a snap fit.

Optionally, the relay housing is can be formed of silicone.

Optionally, an electrical connector can be attached to the other end of the signal cable.

According to a third aspect of the invention, there is provided a relay state sensor array removably attachable to an array of substantially cuboid-shaped relays for sensing the states of the relays, the relay state sensor array comprising a plurality of adjacent relay state sensor devices according to the second aspect of the invention, each relay state sensor device attached to its neighbor at its housing.

According to a fourth aspect of the invention, there is provided an appliance monitoring and reporting system comprising:
one or more data acquisition devices according to any one of the claims, each data acquisition device removably attached to an appliance; and
a local gateway configured:
   i. to receive and process data packets sent by the communications modules of the one or more data acquisition devices; and
   ii. to transmit information indicative of the operation of the corresponding appliances to a remote server, said information based on the received data packets.

### BRIEF DESCRIPTION OF THE DRAWINGS

Various features and advantages of the present invention may be more readily understood with reference to the following detailed description taken in conjunction with the accompanying drawings, wherein like reference numerals designate like structural elements, and in which:

FIG. 1 shows a diagrammatic view of an appliance monitoring and reporting system of the present invention;

FIG. 2 shows a diagrammatic view of a washing machine to be monitored by the appliance monitoring and reporting system of FIG. 1;

FIG. 3 shows a diagrammatic view of an appliance monitoring and reporting system of the present invention, including a data acquisition device of the present invention;

FIG. 4 shows a diagrammatic view of an interface of the data acquisition device of FIG. 3;

FIG. 5A shows a side view of a relay state sensor of the present invention;

FIG. 5B shows a side view of an alternative relay state sensor of the present invention;

FIG. 6 shows a diagrammatic view of the interface, hub and sensors of FIG. 3;

FIGS. 7A and B show diagrammatic views of the connections between an interface of a data acquisition module of an embodiment of the present invention and a washing machine;

FIGS. 8A, B and C show diagrammatic views of the connections between an interface of a data acquisition module of an embodiment of the present invention, a passive hub and an array of sensors;

FIGS. 9A, B and C show diagrammatic views of the connections between an interface of a data acquisition module of an embodiment of the present invention, a passive hub and an array of sensors;

FIG. 10 shows a diagrammatic view of the connections between an interface of a data acquisition module of an embodiment of the present invention and utility meters;

FIG. 11 shows a diagrammatic view of the connections between an interface of a data acquisition module of an embodiment of the present invention and a serial to USB converter;

FIG. 12 shows part of a circuit diagram of an interface of a data acquisition module of an embodiment of the present invention;

FIGS. 13A, B and C show further parts of a circuit diagram of the interface of FIG. 12;

FIGS. 14A, B, C, D and E show further parts of a circuit diagram of the interface of FIG. 12;

FIGS. 15A, B and C show further parts of a circuit diagram of the interface of FIG. 12;

FIGS. 16A, B and C show further parts of a circuit diagram of the interface of FIG. 12;

FIG. 17 shows a printed circuit board of a passive hub of an embodiment of the present invention;

FIG. 18 shows a perspective view of a housing for the printed circuit board of the passive hub of FIG. 17;

FIGS. 19A, B, C and D show multiple cross-sections of the housing of FIG. 18;

FIGS. 20A, B and C show exploded views of the housing of FIG. 18;

FIG. 21 shows a perspective view of a relay state sensor of the present invention;

FIG. 22 shows multiple relay state sensors of the present invention which are removably attached to relays on an output board of a washing machine; and

FIG. 23 shows a single relay state sensor of the present invention which is removably attached to a relay on an output board of a washing machine.

### DETAILED DESCRIPTION OF PREFERRED EMBODIMENTS

To facilitate an understanding of the principles and features of the various embodiments of the invention, various illustrative embodiments are explained below. Although exemplary embodiments of the invention are explained in detail, it is to be understood that other embodiments are contemplated. Accordingly, it is not intended that the invention is limited in its scope to the details of construction and arrangement of components set forth in the following description or examples. The invention is capable of other embodiments and of being practiced or carried out in various ways. Also, in describing the exemplary embodiments, specific terminology will be resorted to for the sake of clarity.

It must also be noted that, as used in the specification and the appended claims, the singular forms “a,” “an” and “the” include plural references unless the context clearly dictates otherwise. For example, reference to a component is intended also to include composition of a plurality of components. References to a composition containing “a” constituent is intended to include other constituents in addition to the one named.

Also, in describing the exemplary embodiments, terminology will be resorted to for the sake of clarity. It is intended that each term contemplates its broadest meaning as understood by those skilled in the art and includes all technical equivalents which operate in a similar manner to accomplish a similar purpose.

Ranges may be expressed herein as from “about” or “approximately” or “substantially” one particular value and/or to “about” or “approximately” or “substantially” another particular value. When such a range is expressed, other exemplary embodiments include from the one particular value and/or to the other particular value.

Similarly, as used herein, “substantially free” of something, or “substantially pure”, and like characterizations, can include both being “at least substantially free” of something, or “at least substantially pure”, and being “completely free” of something, or “completely pure”.

By “comprising” or “containing” or “including” is meant that at least the named compound, element, particle, or method step is present in the composition or article or method, but does not exclude the presence of other compounds, materials, particles, method steps, even if the other such compounds, material, particles, method steps have the same function as what is named.

It is also to be understood that the mention of one or more method steps does not preclude the presence of additional method steps or intervening method steps between those steps expressly identified. Similarly, it is also to be understood that the mention of one or more components in a composition does not preclude the presence of additional components than those expressly identified.

The materials described as making up the various elements of the invention are intended to be illustrative and not restrictive. Many suitable materials that would perform the same or a similar function as the materials described herein are intended to be embraced within the scope of the invention. Such other materials not described herein can include, but are not limited to, for example, materials that are developed after the time of the development of the invention.

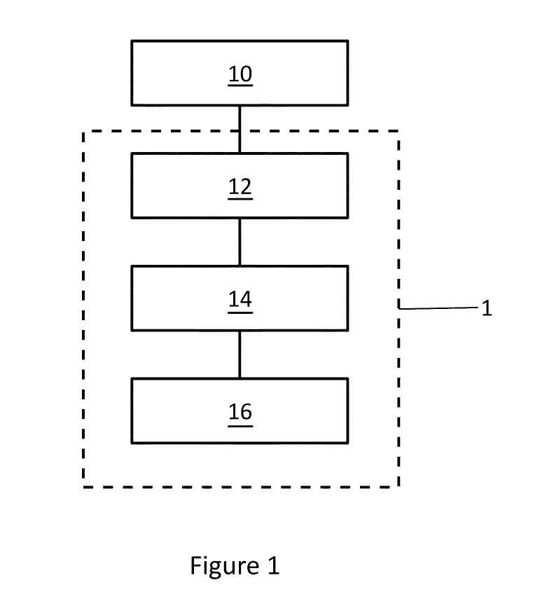

Referring to FIG. 1, an appliance monitoring and reporting system 1 of the present invention comprises a data acquisition device 12 which is removably attached to an appliance 10. Removable attachment of the data acquisition device 12 to the appliance 10 refers to a removable fixing or fastening of one or more sensors (not shown) of the data acquisition device 12 to one or more components of the appliance 10 and can also refer to a removable electrical connection of the data acquisition device 12 to an output of an appliance 10. Where sensors are fixed or fastened to components of the appliance 10, the sensors are typically electrically isolated from the components. Thus, the data acquisition device 12 is detachable from the appliance 10, and in particular the attachment, connection, fixation or fastening of the device 12 to the appliance 10 is reversible without significant structural modification of the appliance 10 and without alteration of the operation of the appliance. Preferably the device 12 of the present invention is intended to be removable from the appliance 10 without a trace.

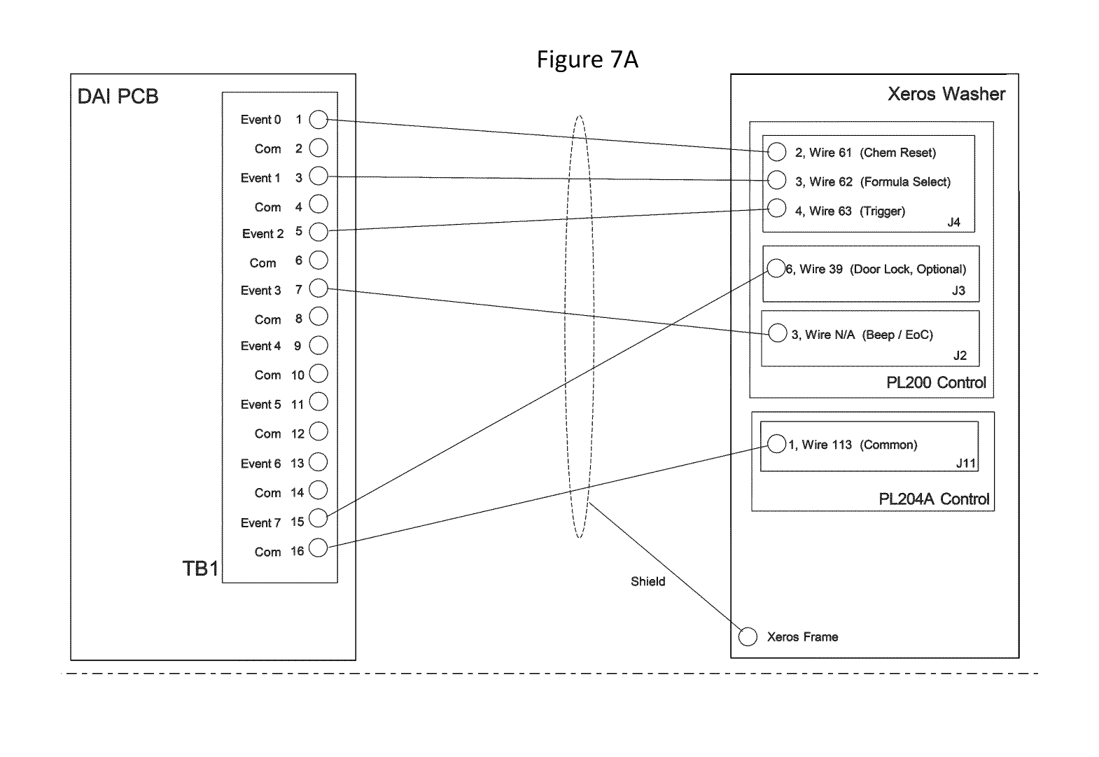

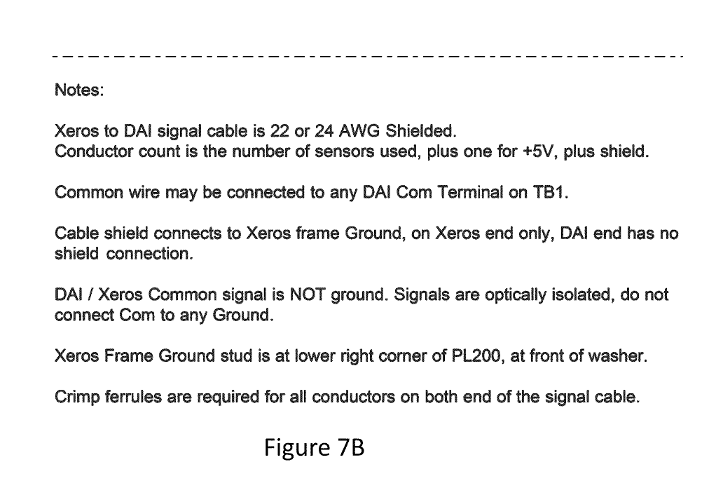

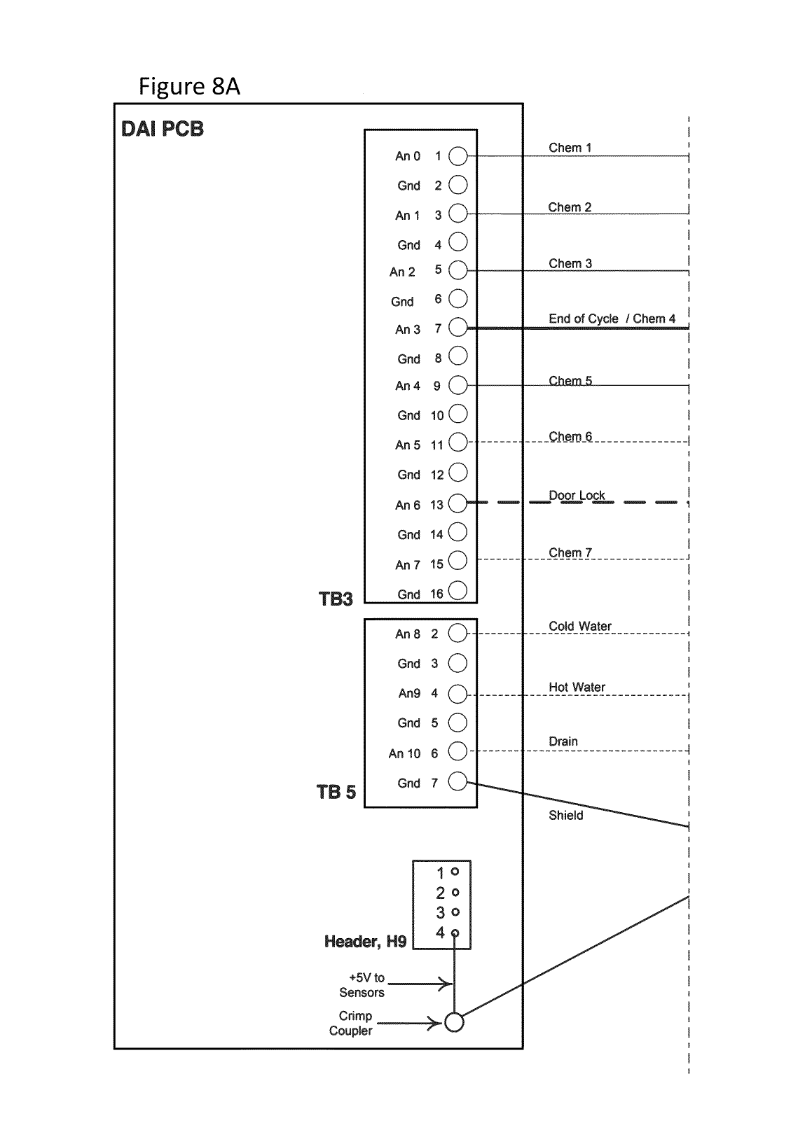

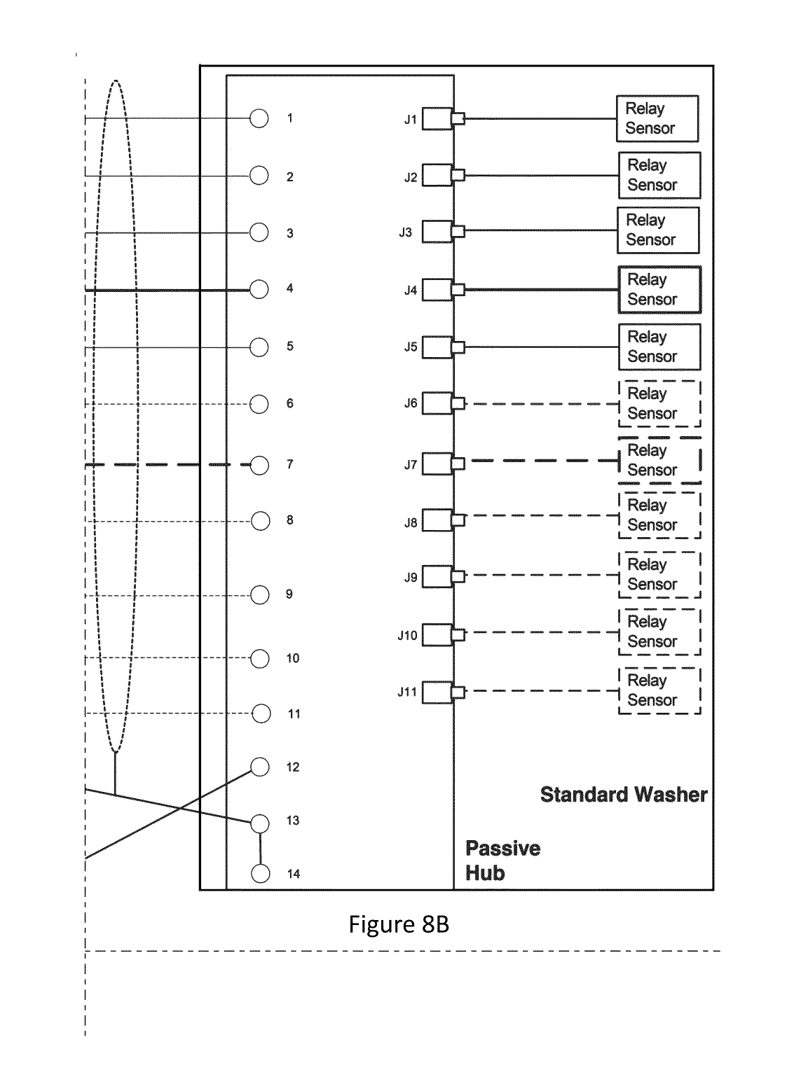

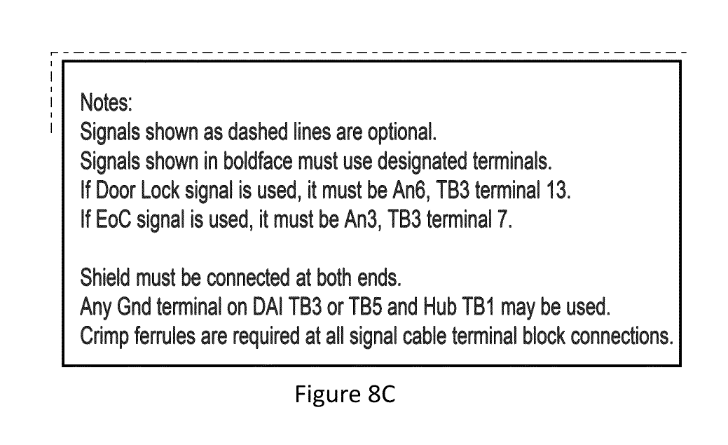

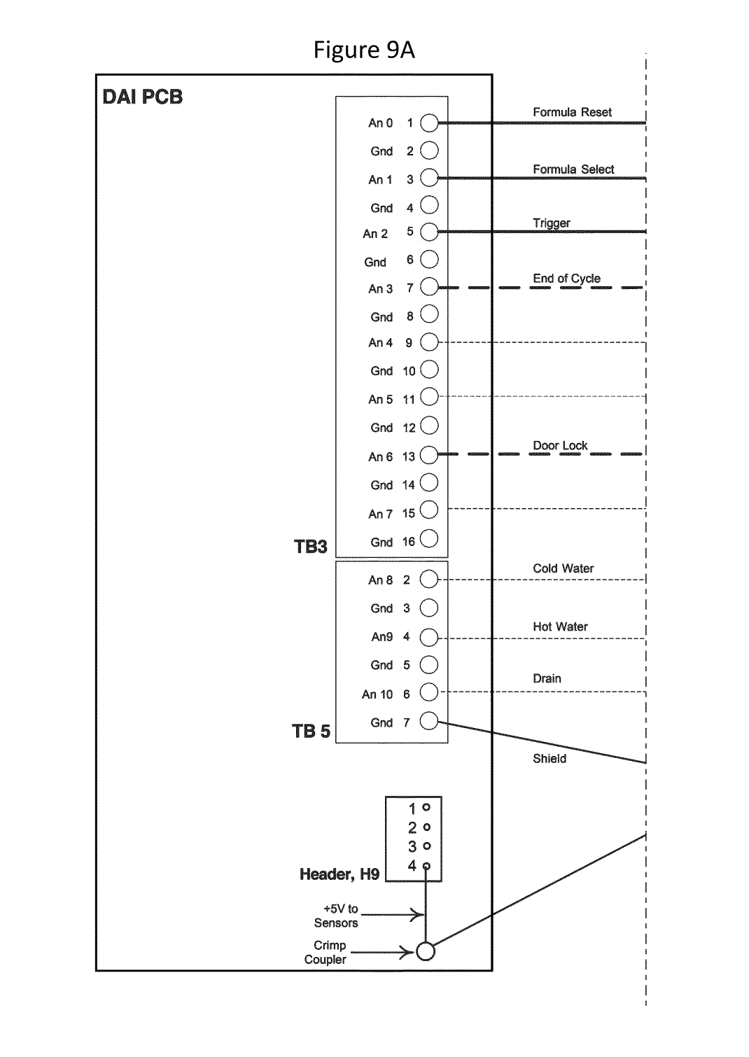

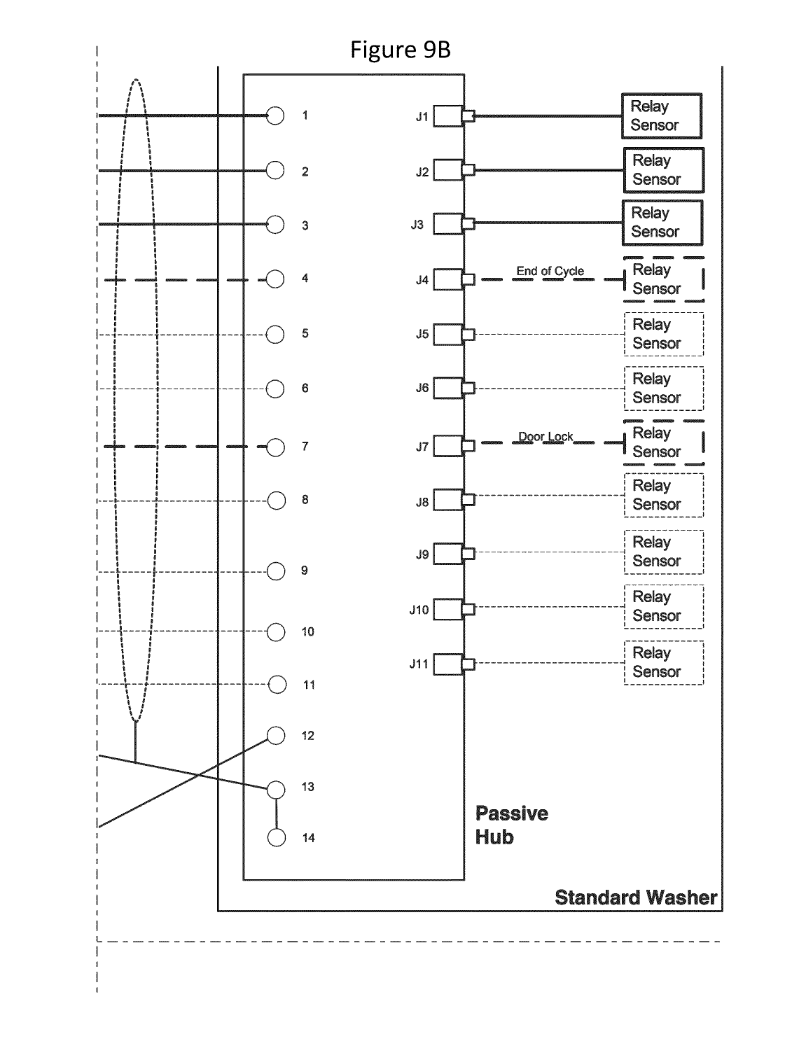

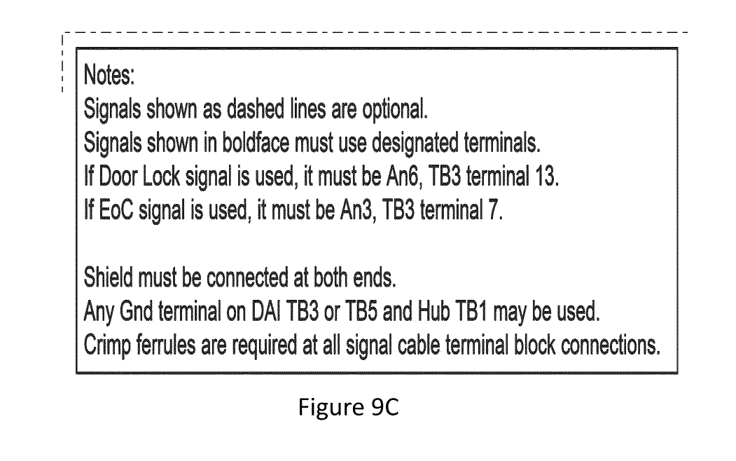

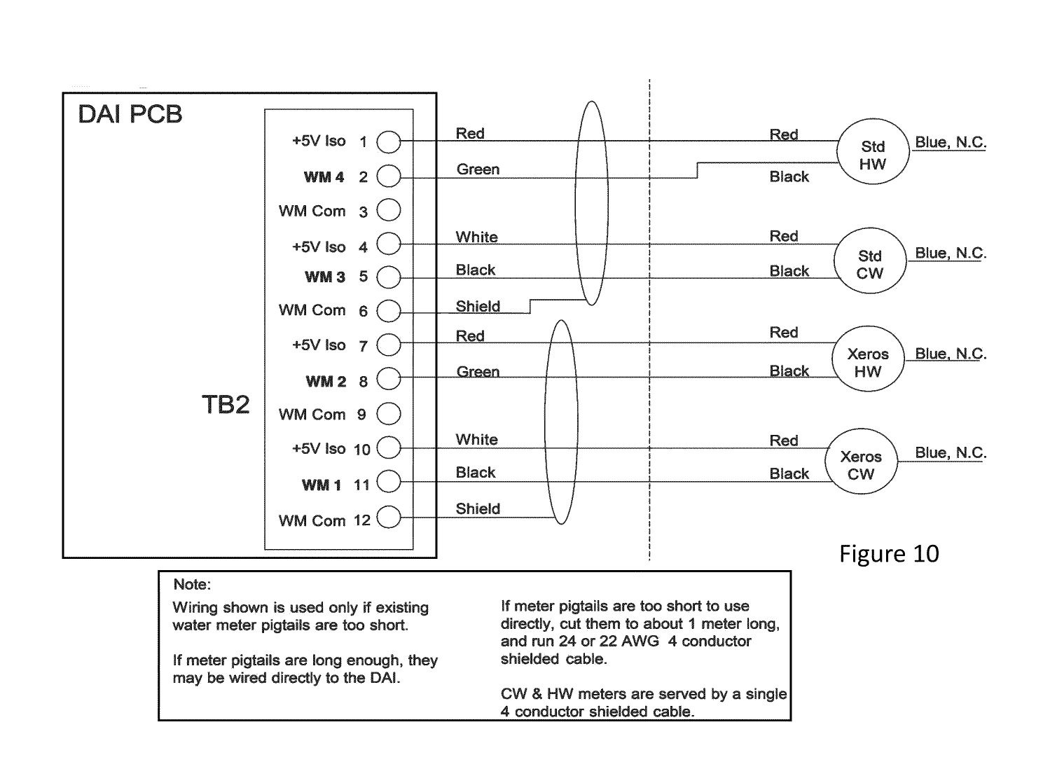

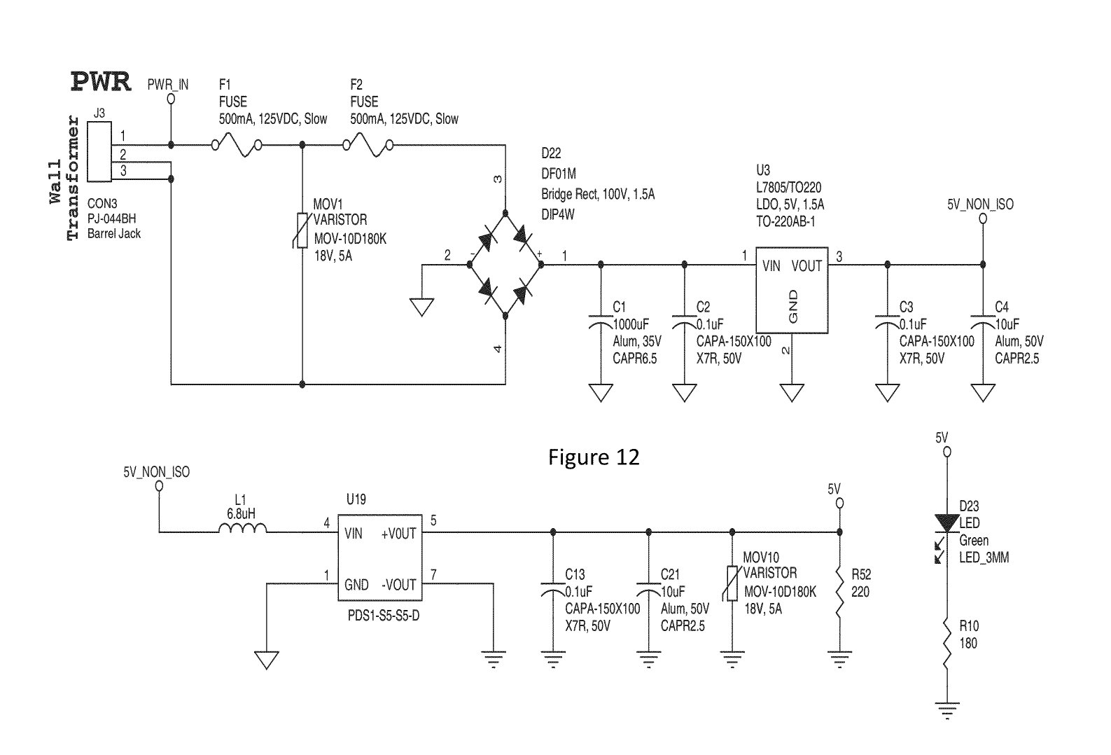

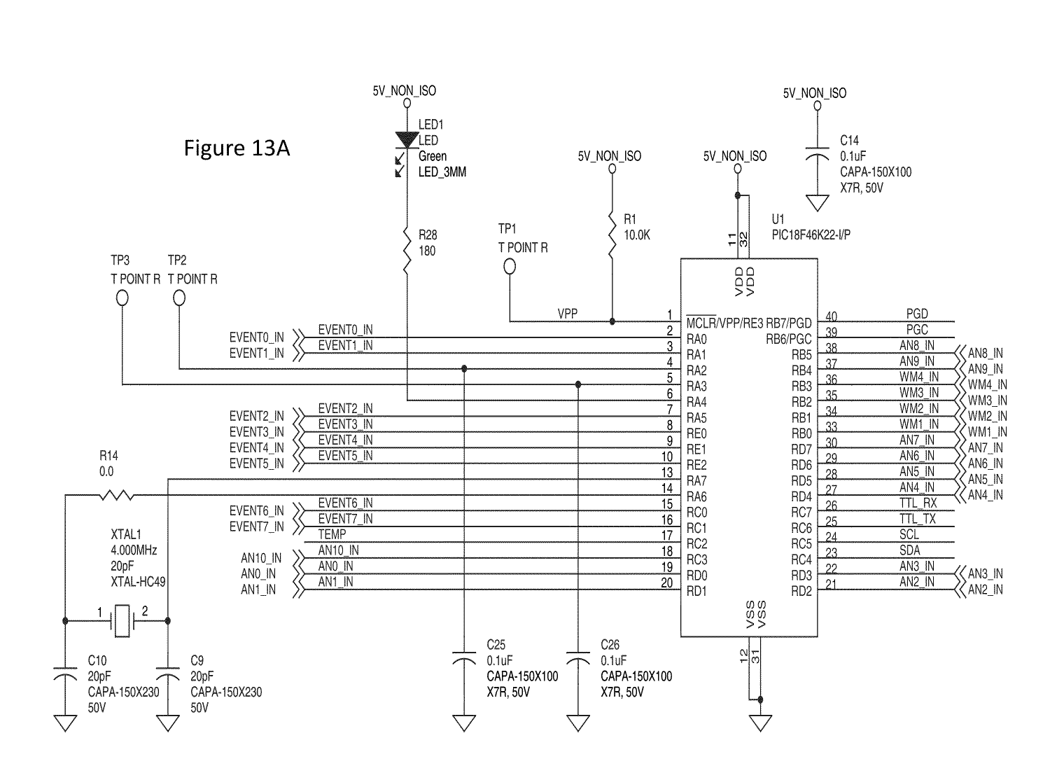

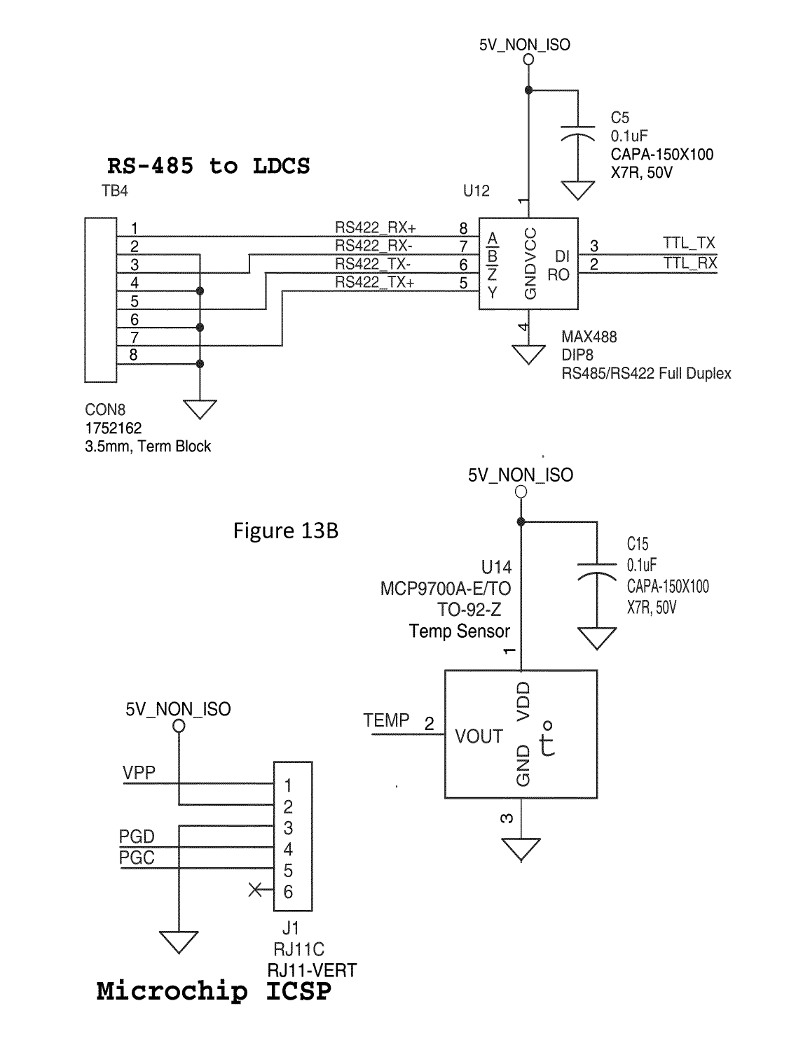

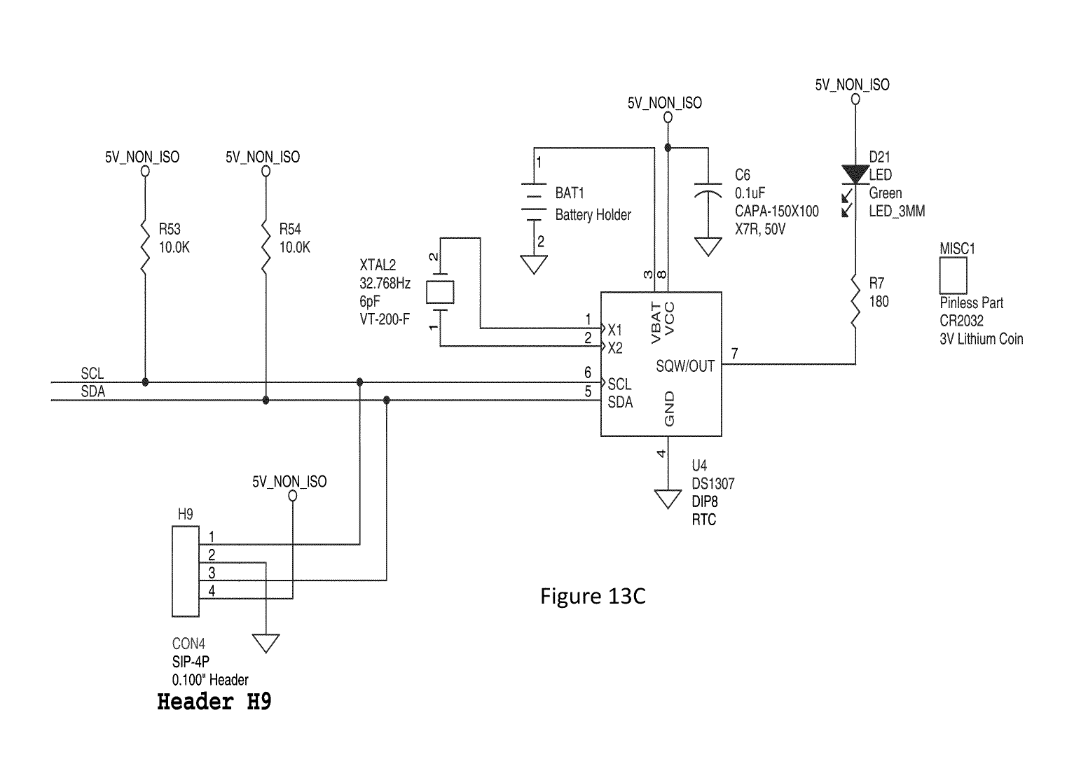

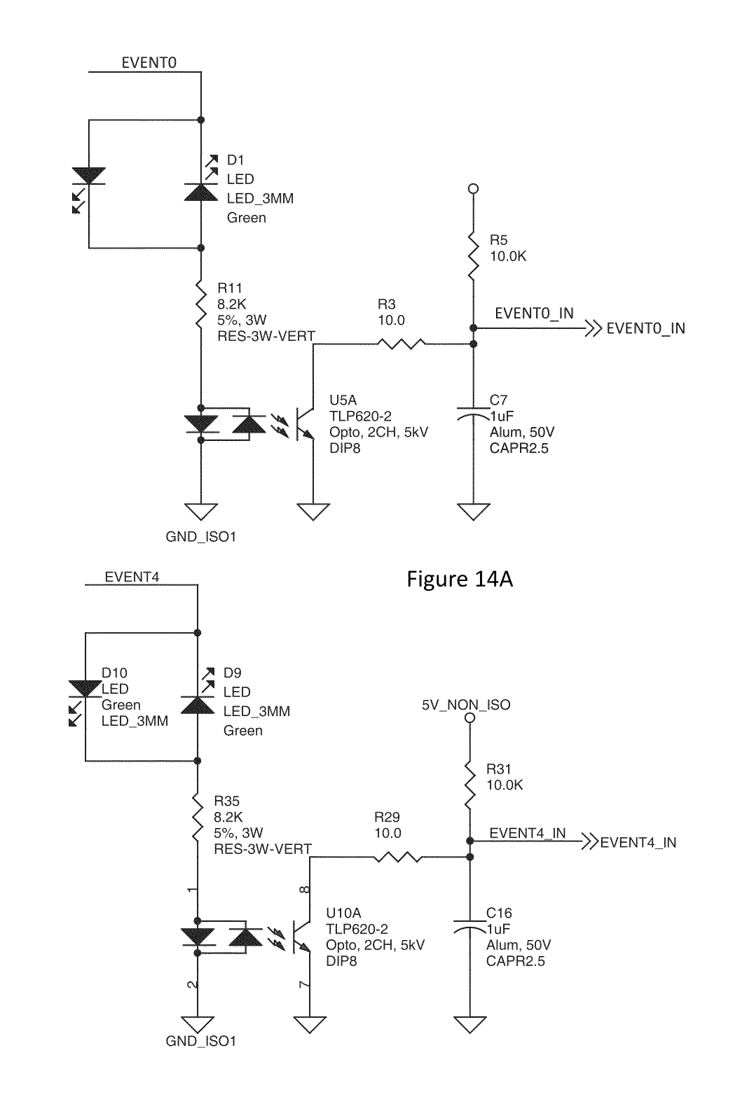

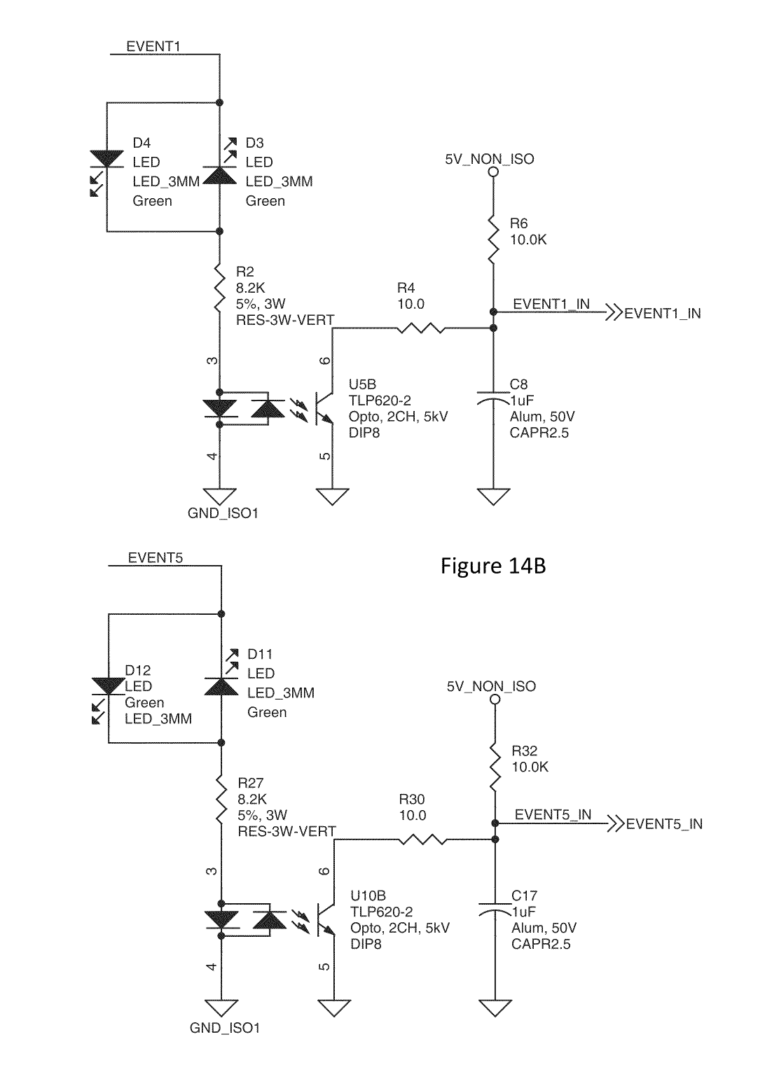

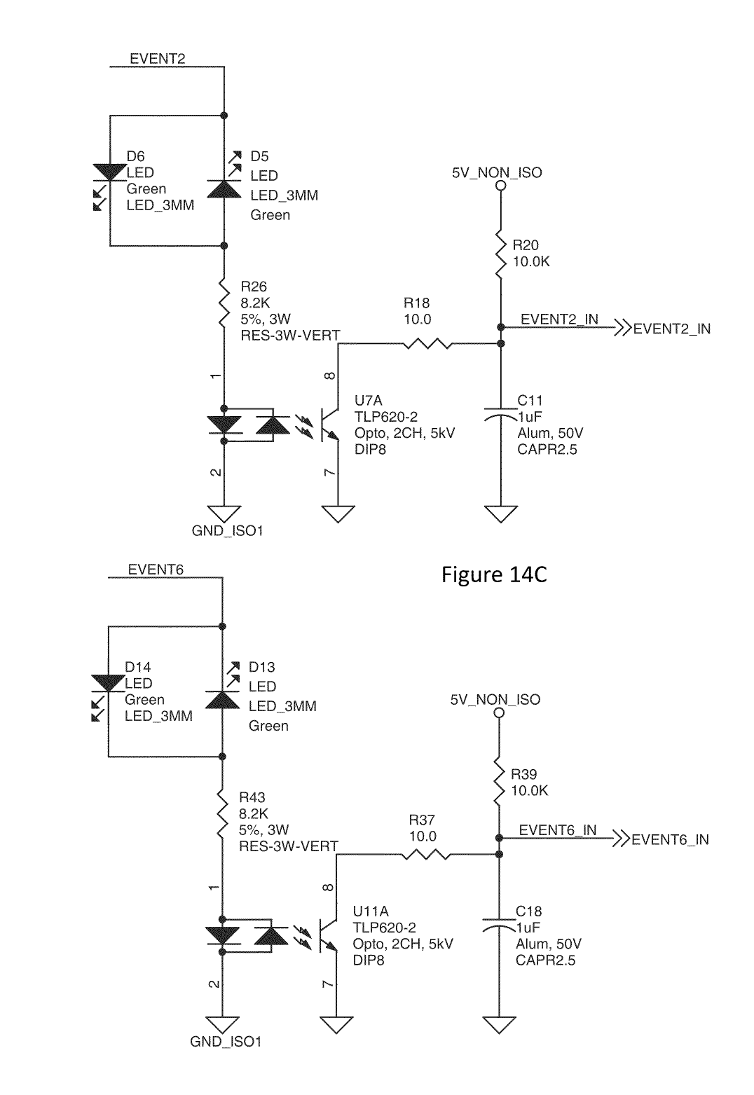

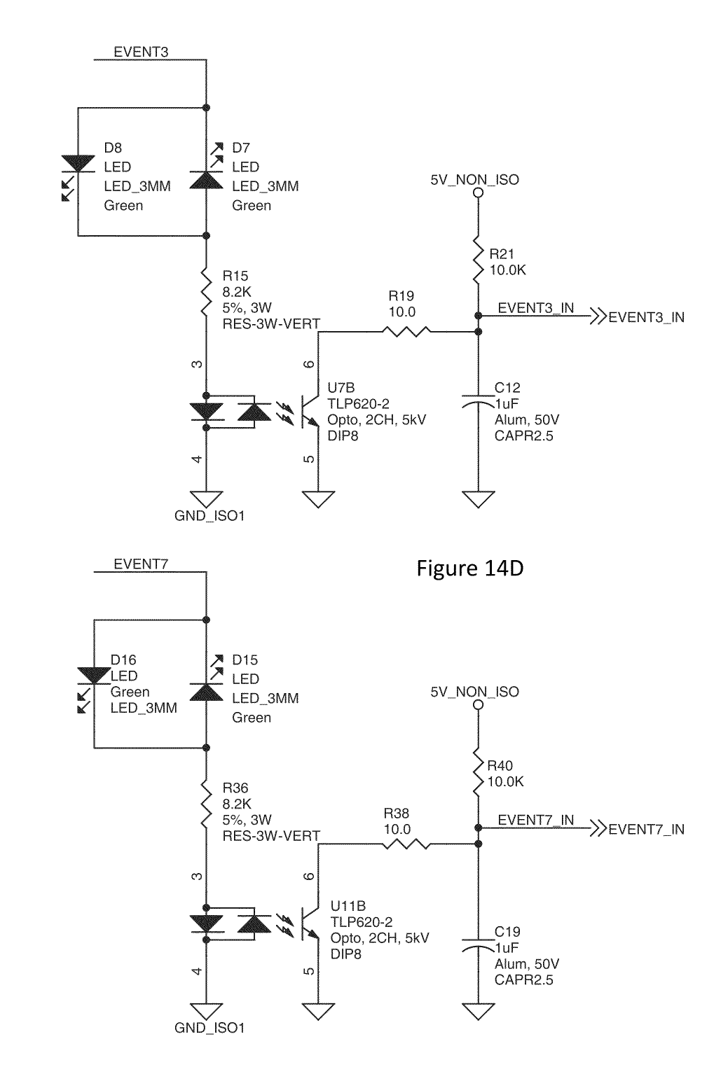

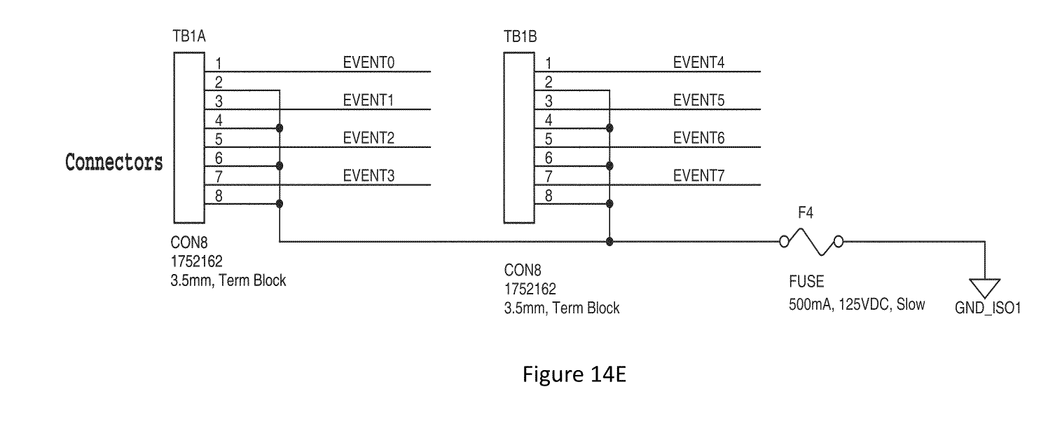

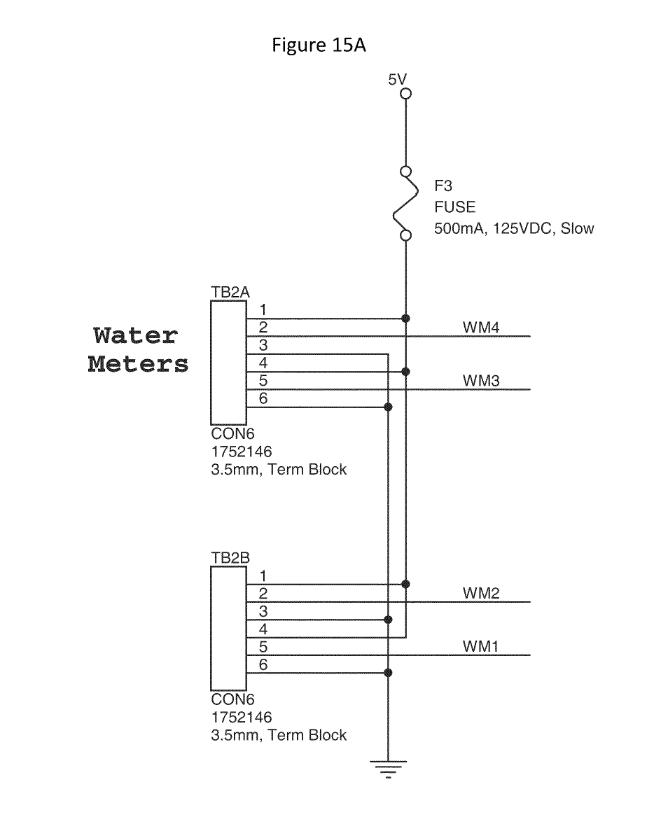

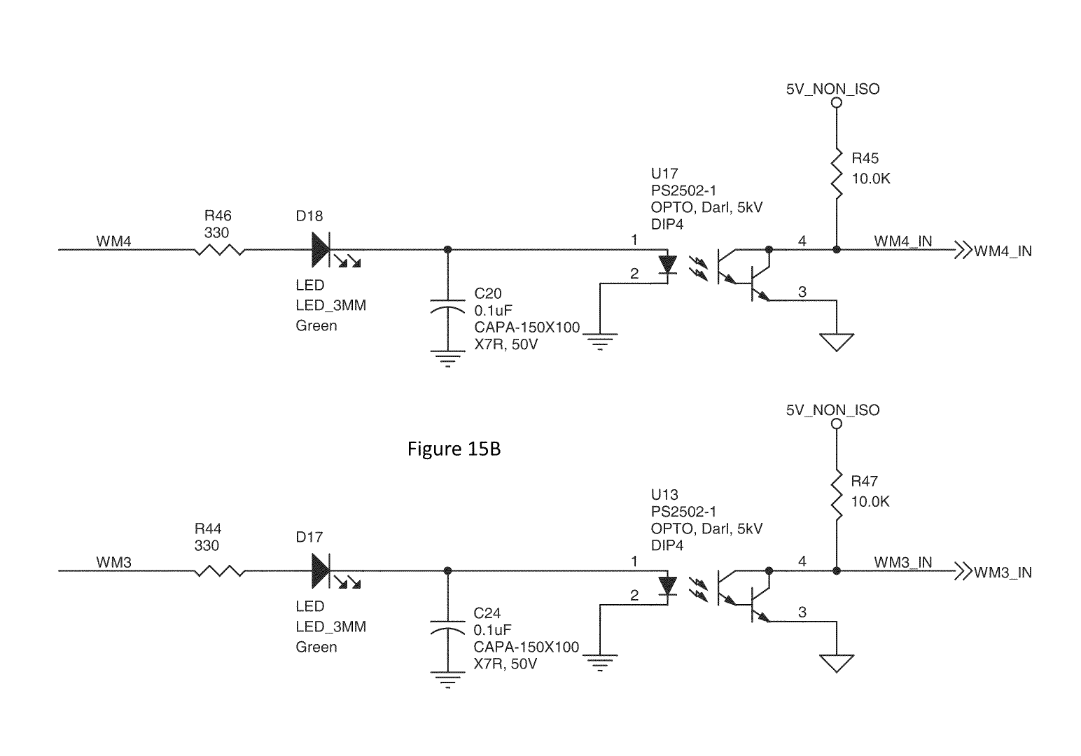

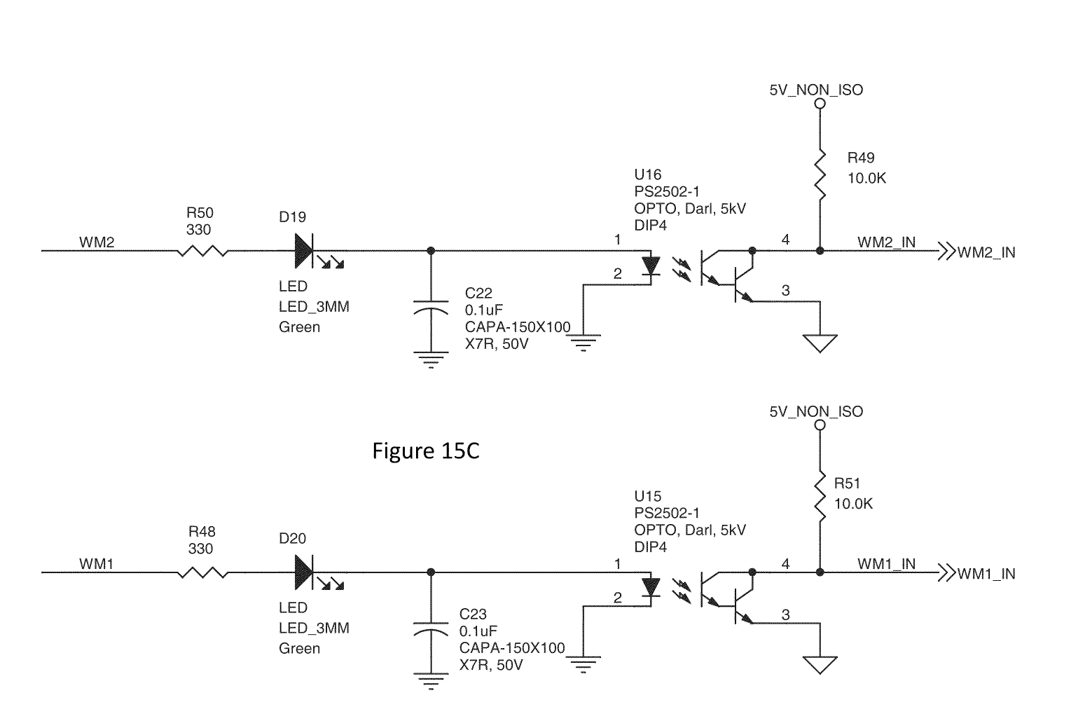

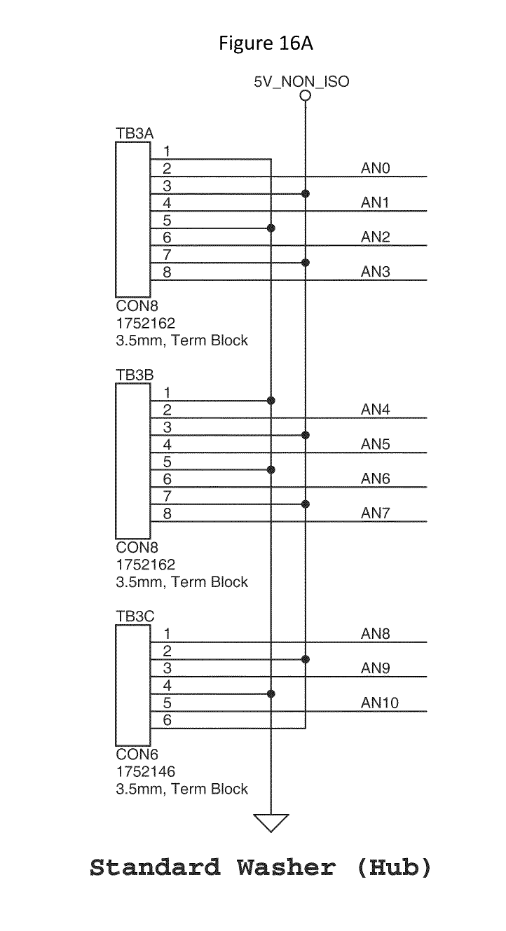

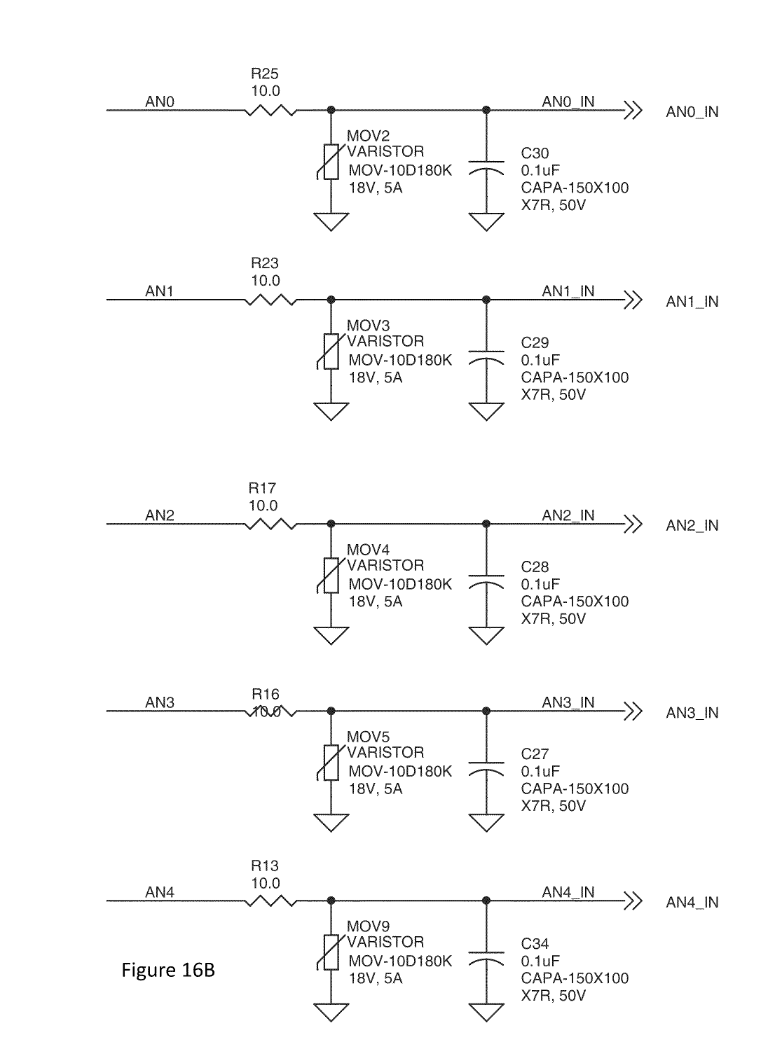

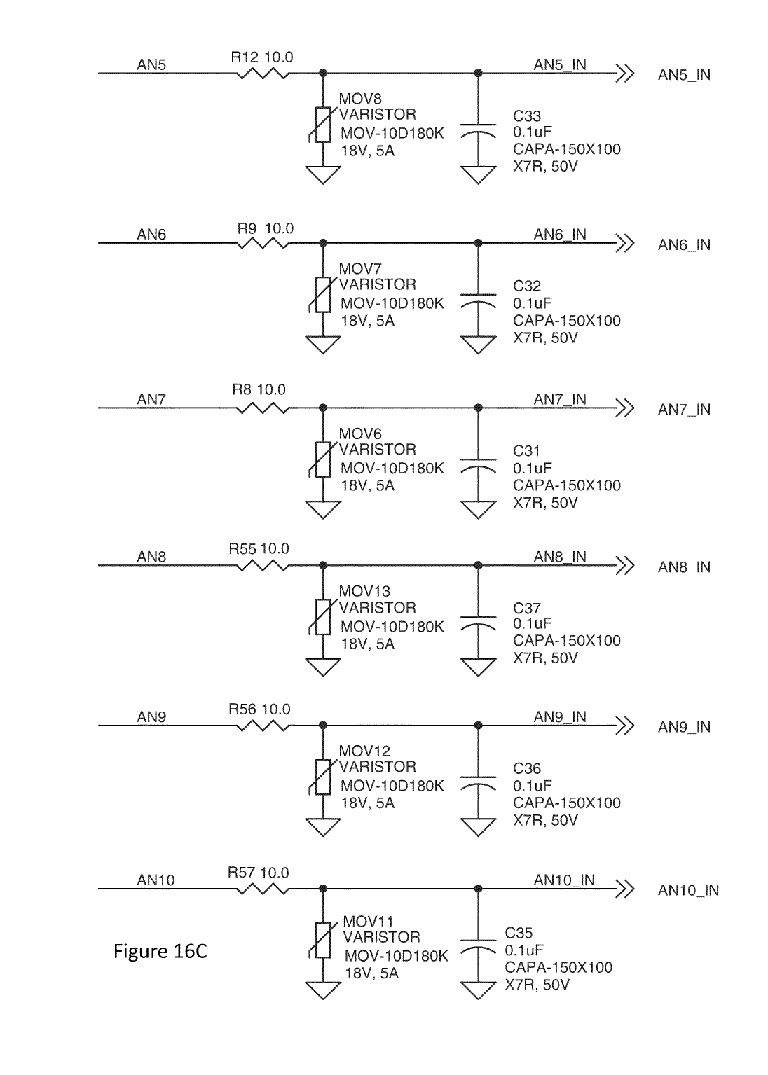

An interface of the data acquisition device 12 is configured to receive signals from the one or more sensors attached to the one or more components of the device and comprises a processor configured to process the signals received from the one or more sensors and generate a data packet containing data indicative of operation of the appliance based on the received signals. In some embodiments, data indicative of the operation of the appliance may be data which indicates an event in a cycle of operation of the appliance. For example, if the appliance is a washing machine, data indicative of operation of the washing machine would include indications of the start or end times of a cycle, door lock and unlock, chemical request signals and drain valve opening or closing. FIGS. 12 and 13A-C are circuit diagrams of an exemplary embodiment of an interface according to an embodiment of the invention. FIGS. 7A-B, 14A-E and 16A-C are circuit diagrams of exemplary connections between an interface of a data acquisition module and an appliance according to embodiments of the invention. FIGS. 8A-C and 9A-C are circuit diagrams of exemplary connections between an interface of a data acquisition module and an array of sensors, via a hub, according to embodiments of the invention. FIGS. 10 and 15A-C are circuit diagrams of exemplary connections between an interface of a data acquisition module and utility meters according to embodiments of the invention.

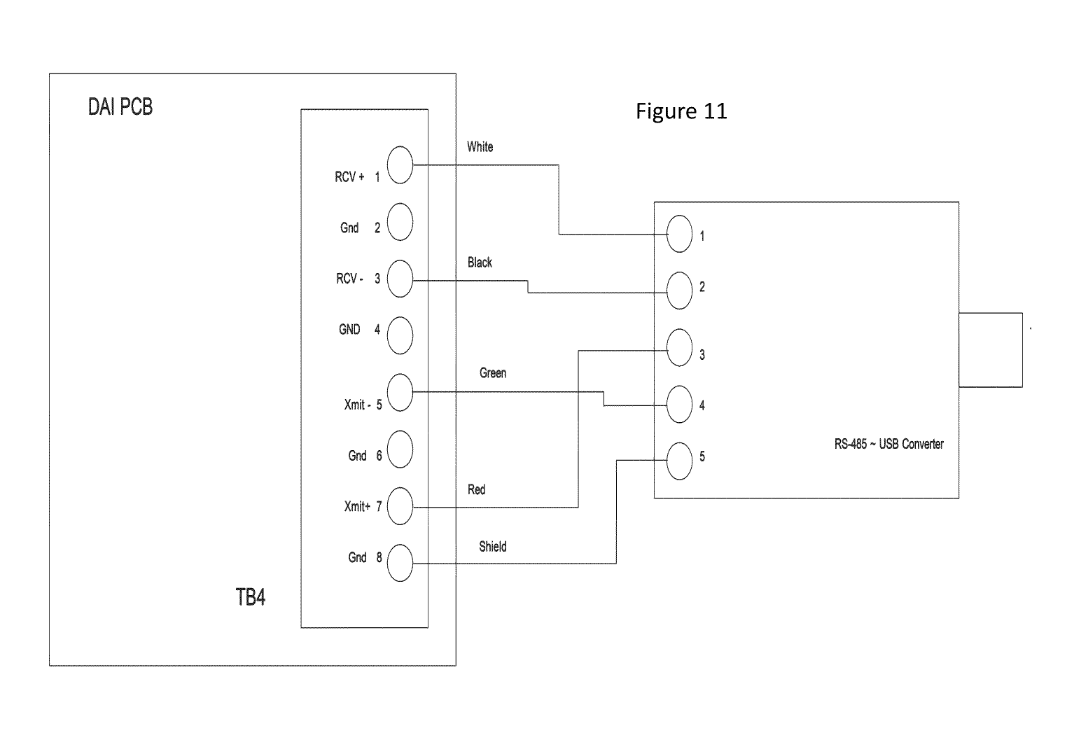

The interface of the data acquisition device 12 further comprises a communications module (not shown) configured to transmit data packets generated by the processor to a local gateway 14. The data acquisition device 12 is connected to the local gateway 14 via a wired connection, although this is not essential and the data acquisition device could communicate with the local gateway wirelessly. The local gateway 14 is configured to receive and process the data packets sent by the data acquisition device 12, as described in more detail below. FIG. 11 is a circuit diagram of an exemplary connection of an interface of a data acquisition module with a serial to USB converter for attachment of the data acquisition module to a local gateway according to an embodiment of the invention.

The local gateway 14 is further configured to transmit information indicative of the operation of the appliance, based on the received data packets from the data acquisition device 12, to a remote server 16, preferably over an internet connection.

The interface of the data acquisition device 12 is configured as a ‘store and forward’ device, which is programmed to receive signals at the at least one input, store the signals in a memory for a period of time, process the signals into a data packet and forward the data packet to local gateway 14. The local gateway 14 is configured to store the received data packet from the interface, process the received data and transmit data indicative of operation of the appliance to a remote server over a network connection (typically an Internet connection). Typically, the remote server is configured for storage and display of the data to a user connected to the server over the network.

Although it is envisaged that the present invention can be applicable to any appliance, the invention will be described hereafter specifically in relation to washing machines.

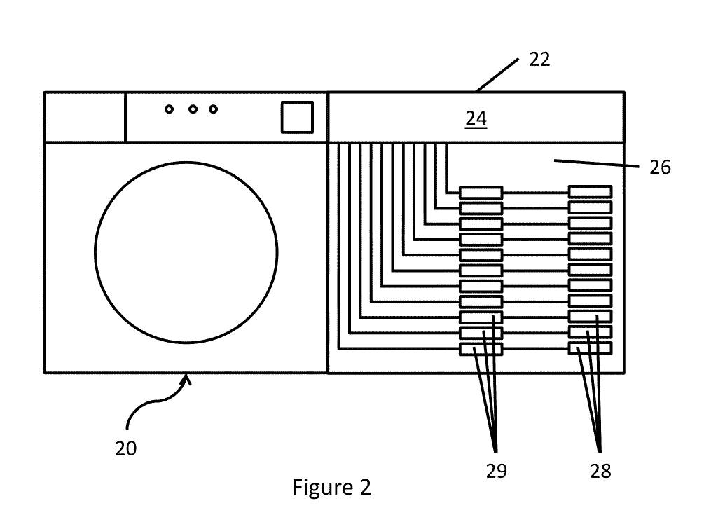

Referring to FIG. 2, a washing machine 20 has a controller 22 comprising a processor board 24 connected to an input-output (I/O) board 26. The I/O board 26 comprises eleven outputs 28 connected to components of the washing machine. Each of the outputs 28 of the I/O board 24 include a switch 29 to isolate the power circuits of the processor board 24 from the circuits of the components of the washing machine 20, which are relatively high power compared to the processor circuits. In use, the I/O board 26 forwards operating signals from the processor board 24 to the components of the washing machine, via the switches 29, to cause the washing machine to carry out various washing machine functions of a washing operation.

It is a realization of the present invention that a data acquisition device can be used to sense operating signals at an output of an I/O board of a washing machine and determine information about an aspect of the operation of the washing machine from the operating signal.

For example, an output signal at an output associated with a door unlock solenoid indicates that the processor has signaled for the door of the washing machine to be unlocked. Typical outputs of an I/O board include, amongst others: chemical 1, chemical 2, chemical 3, chemical 4, chemical 5, chemical 6, chemical 7, chemical 8, hot water valve, cold water valve, sewer drain solenoid, flush valve, steam valve, alarm state solenoid, lint filter lock solenoid, door latch solenoid.

It is a further realization of the present invention that an operating signal of an I/O board can be detected by sensing a switching event of a switch of the I/O board associated with the output. For example, the switches 29 of the I/O board 26 are electromechanical relay switches, each relay having an active state and an inactive state. A switching event of a relay from an inactive state to an active state or vice versa can be sensed by a magnetic field sensor, and in particular a Hall effect sensor, positioned along the axis of the solenoid of the relay. Typical relays of I/O boards include:

a relay, the state of which is indicative of the end of a cycle of operation of the appliance;

a relay, the state of which is indicative of the door lock status of the appliance; and

a relay, the state of which is indicative of the drain input status of the appliance.

The number and arrangement of outputs and switches of an I/O board are specific to each I/O board design. Examples of typical I/O boards include: V6J uP produced by Milnor and CXR output board produced by Cissell.

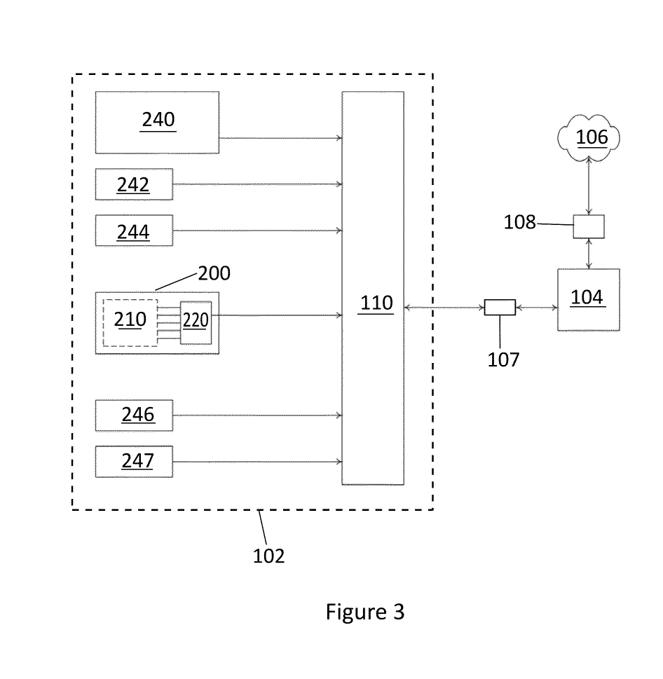

Referring to FIG. 3, an exemplary monitoring and reporting system 100, for monitoring the washing machine 20 of FIG. 2, comprises a data acquisition device 102, a local gateway 104 and a remote server 106. The data acquisition device 102 is connected to the local gateway 104 via a wired connection. A serial to USB converter 106 is disposed between the data acquisition device 110 and the local gateway 104 to convert a serial output (typically RS-485) from the data acquisition device to USB protocol readable by the local gateway 104. The local gateway 104 is connected to the remote server 106 via a network connection 108.

The data acquisition device 102 comprises an interface 110 having a plurality of inputs for receiving data from a plurality of sources. The device 102 further comprises a relay state sensor array 200 including an eleven relay state sensors 210. Each relay state sensor 210 is connected to a hub 220 and an output of the hub 220 is connected to an input of the interface 110.

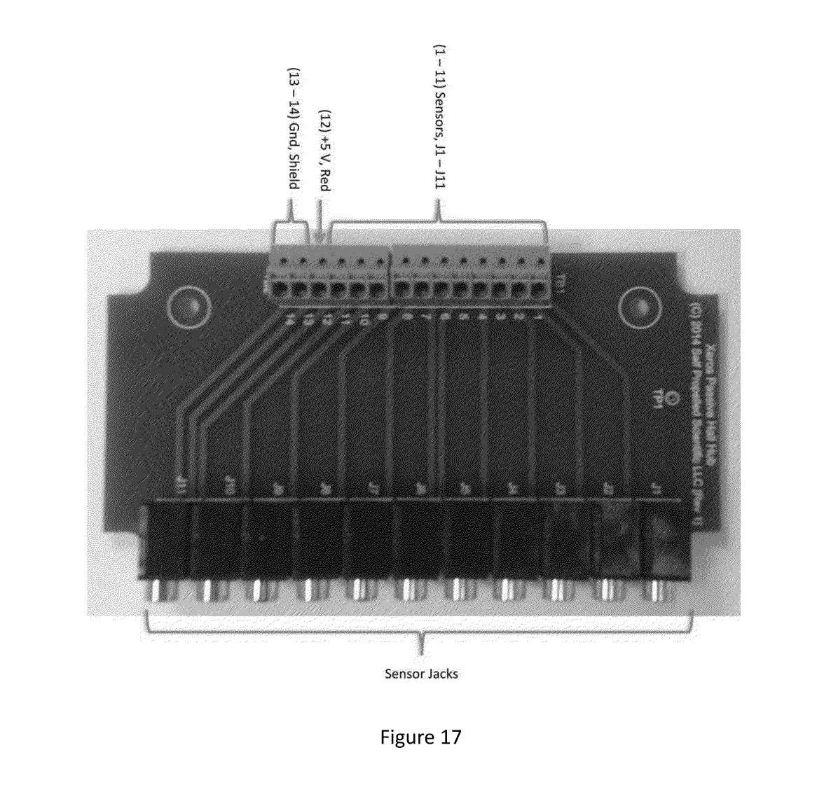

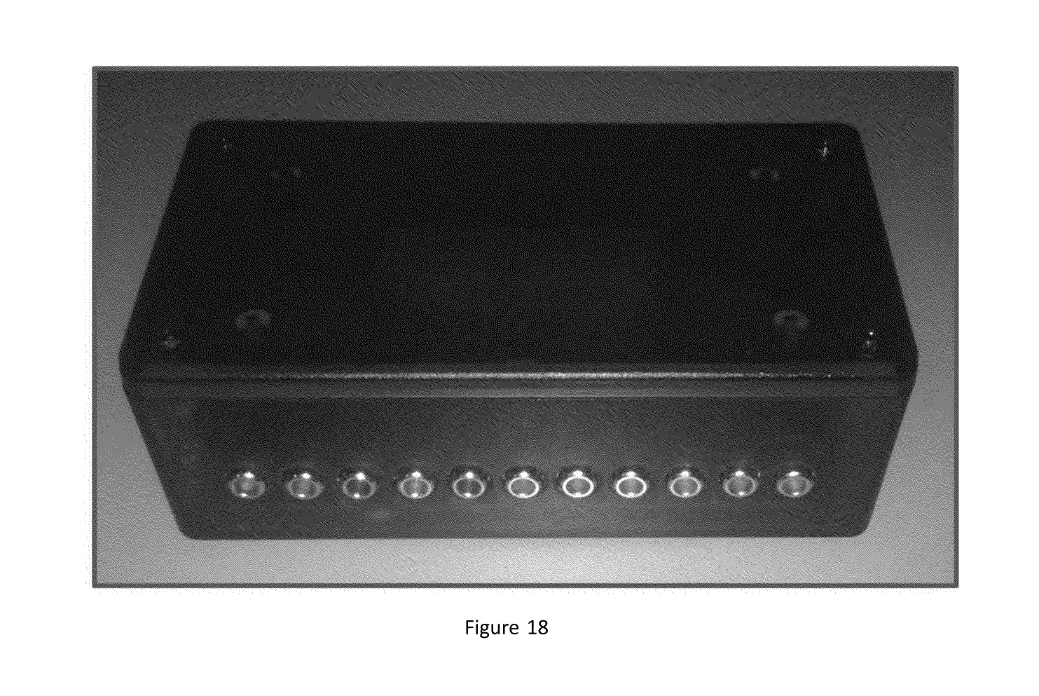

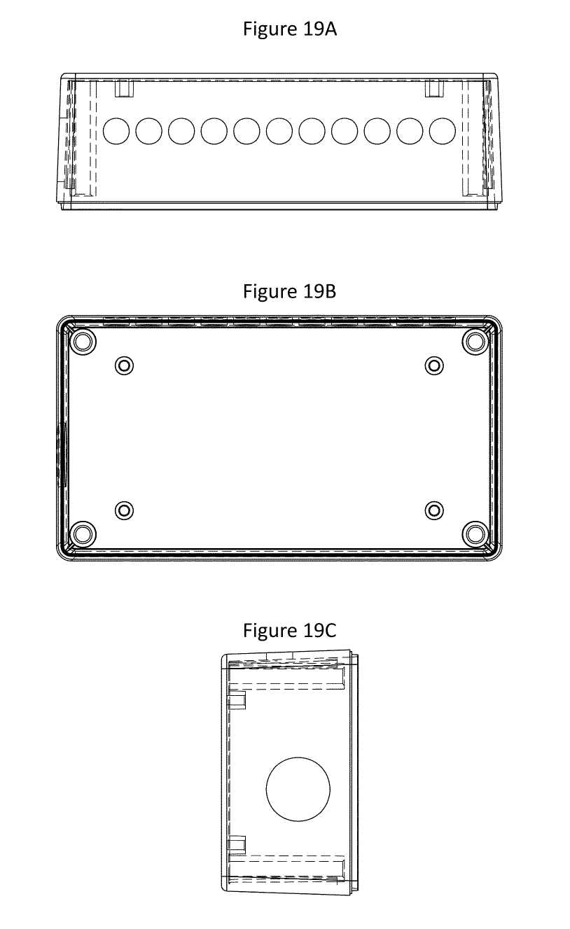

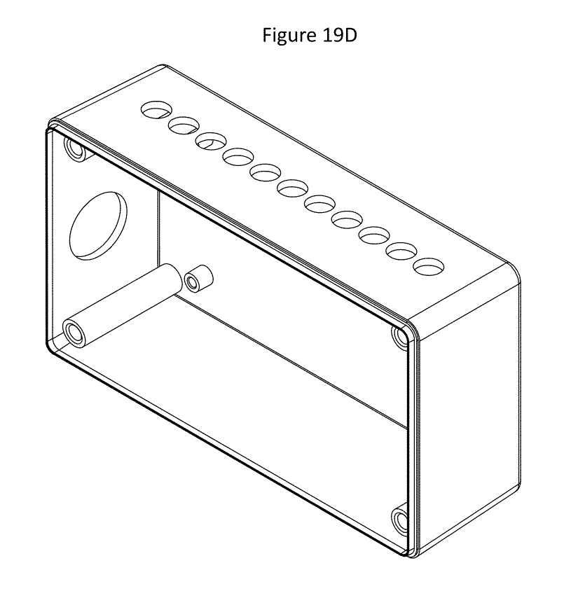

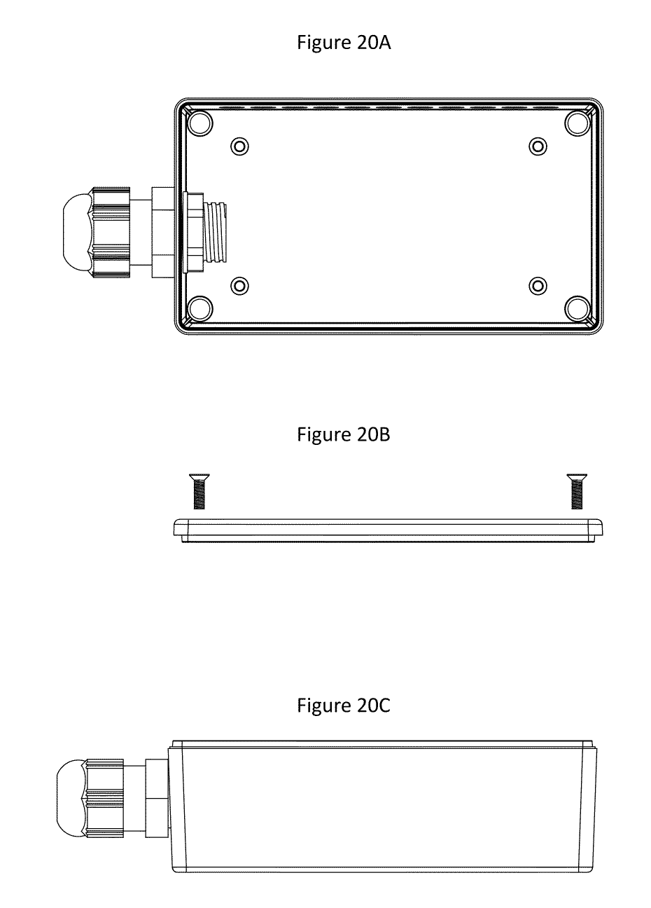

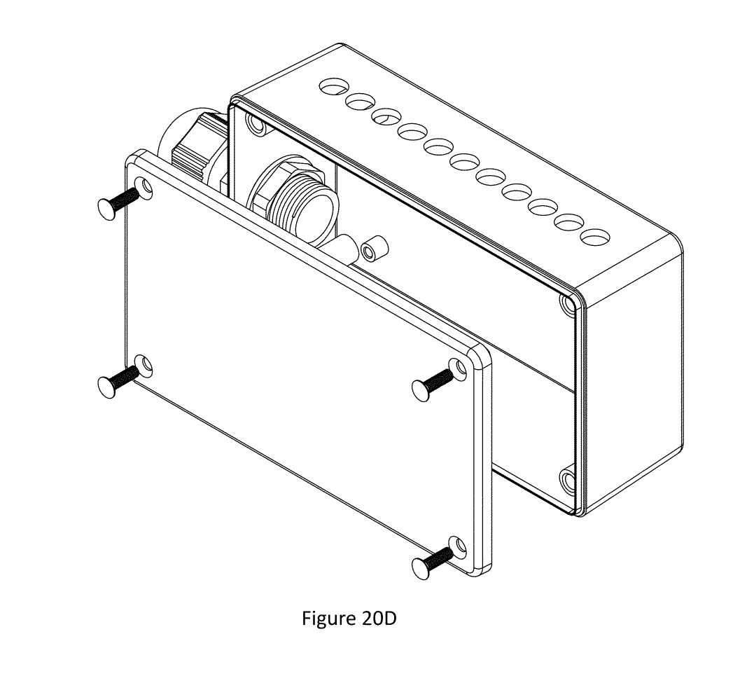

The hub 220 is a passive hub device for connecting output wires from the sensors 210 with respective inputs of the interface 110. The hub 220 comprises a printed circuit board within a housing, the printed circuit board having connectors for receiving outputs of each of the sensors and a terminal block for connection an output of the hub to one or more inputs of the interface. FIG. 17 is an image of a printed circuit board of a hub according to an embodiment of the invention. FIGS. 18, 19A-D and 20A-D are images of housing for the printed circuit board of a hub according to embodiments of the invention.

The interface 110 also comprises an input for an output 240 of the washing machine 20. Typically the output of the washing machine carries a formula select signal or a formula reset signal intended for an automatic chemical product dispenser.

The interface 110 also comprises inputs for hot and cold water meter outputs 242 and 244 and other utility meter outputs 246, 247. Typically, utility meters, such as water meters, comprise reed switches which provide signals in the form of magnetic pulses generated as a result of the operation of the water meters and which are indicative of the volume of the utility that has been consumed.

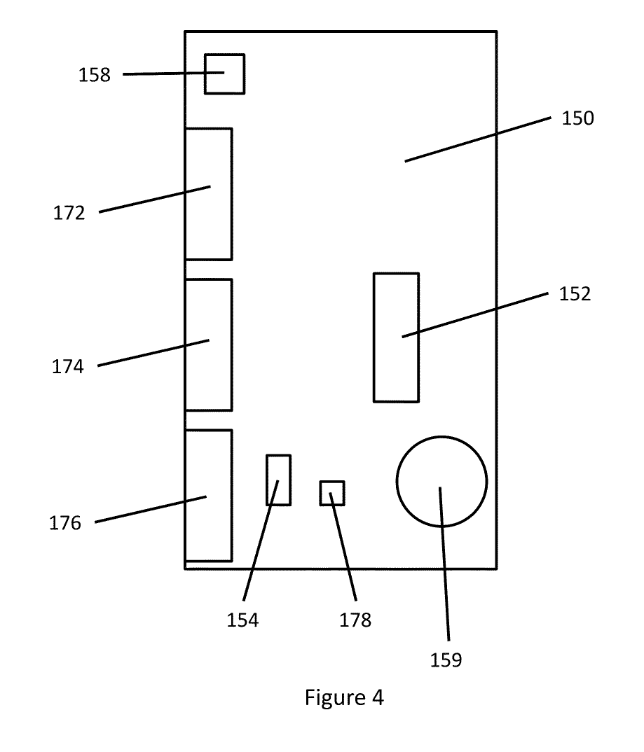

Referring to FIG. 4, the interface 110 of FIG. 3 comprises a printed circuit board 150.

A microcontroller 152 (an integrated circuit (IC), typically a PIC18F46K222 manufactured by MICROCHIP) is mounted to the printed circuit board 150 and comprises an integrated processor and non-volatile memory. An output of the microcontroller 152 is connected to a communications module 154 (typically an RS-485 transceiver such as a MAX488 manufactured by Maxim) also mounted to the printed circuit board 150.

Two groups 172, 174 of terminal blocks are mounted to the printed circuit board 150 and connected to inputs of the microcontroller 152. The first group 172 of terminal blocks is provided for receiving outputs from the relay state sensors 210 of the relay state sensor array 200 and also for providing a 5V DC power supply to the relay state sensors 210. The second group 174 of terminal blocks is provided for receiving outputs from hot and cold water meters and other utility meters.

A third group 176 of terminal blocks is provided for an output of the communications module 154, to connect an output of the microcontroller to the local gateway 104 via the serial-to-USB converter 107.

A connector 178 is also mounted on the printed circuit board 150 for connection of an output 240 of the washing machine 20. The output 240 of the washing machine is typically a wire carrying a formula select signal to an automated chemical product dispenser, the signal being indicative of a request for chemicals from the washing machine.

A connector socket 158 for a 5V DC external power supply (typically from a mains adapter) is mounted on the printed circuit board 150 to provide power to the microcontroller 152, the communications module 154 and to the relay state sensor array 200. A rechargeable battery 159 is also provided on the printed circuit board 150 to provide back-up power in the event that an external power supply is not available.

In use, the interface 110 receives signals from the various inputs, indicative of aspects of the operation of the washing machine 20, such as chemical request signals, hot/cold water valve operation, sewer drain solenoid activation, flush valve operation, steam valve operation, alarm state solenoid activation, lint filter lock solenoid activation and door latch solenoid activation. The microcontroller 152 of the interface is programmed to determine the start and end of a cycle of operation of the washing machine 20. A start of a cycle of operation of the washing machine 20 is typically determined on receipt of a signal from a sensor monitoring a relay controlling a door latch of the washing machine, but may also be determined based on receipt of signals from relays monitoring any aspect of operation of the washing machine, such as a formula request signal, an alarm state solenoid activation or hot/cold water valve operation. An end of a cycle is typically determined on receipt of an opposite signal from the relay controlling the door latch, but may also be determined based on receipt of signals from any of the relays being monitored by a sensor.

During a cycle of operation, the microcontroller is programmed to store the received data from all of the inputs. In particular, the microcontroller is programmed to store the length (duration) of the received signals and the order in which the signals are received. Once an end of a cycle of operation is determined, the microcontroller is programmed to collate the data received and stored during the cycle into a data packet and is further programmed to transmit the data packet to the local gateway via the communications module 154 and the serial-to-USB converter 107.

The microcontroller 152 is further programmed to send the data received from the utility meters at a different time to the sensor data and washing machine output data. For example, the utility meter data may be stored and sent to the local gateway once per day.

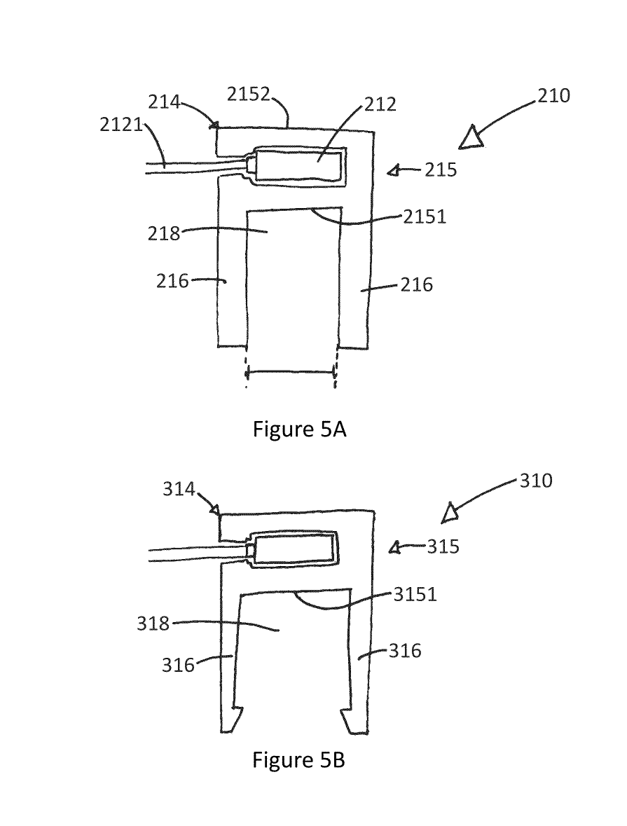

Referring to FIG. 5, a relay state sensor 210 comprises a relay housing 214 having a roof 215 with opposing first and second planar surfaces 2151, 2152 and four opposing walls 216 depending from the first planar surface 2151 of the roof 215.

The four opposing walls 216 and first planar surface 2151 form an open cavity 218 for receiving a relay 29 of the washing machine 20. Relays 29 of the washing machine 20 are substantially cuboid-shaped, having substantially planar upper surface and side walls. The cavity is sized to receive the relay 20 with an interference fit (the distance between the walls 216 of the housing 214 being fractionally less than the width and length of the relay 29 to be received, such that the relay contacts all four opposing walls 216 and is held in place in the cavity 218 by friction.

A magnetic field sensor 212 (typically a Hall effect sensor) is embedded within the second planar surface 2152 of the roof 215. The sensor is oriented within the housing 214 such that it senses changes in magnetic field due to activation and deactivation events of a relay held within the cavity 218. The sensor has a signal cable 2121 extending from the second planar surface and to a hub 220.

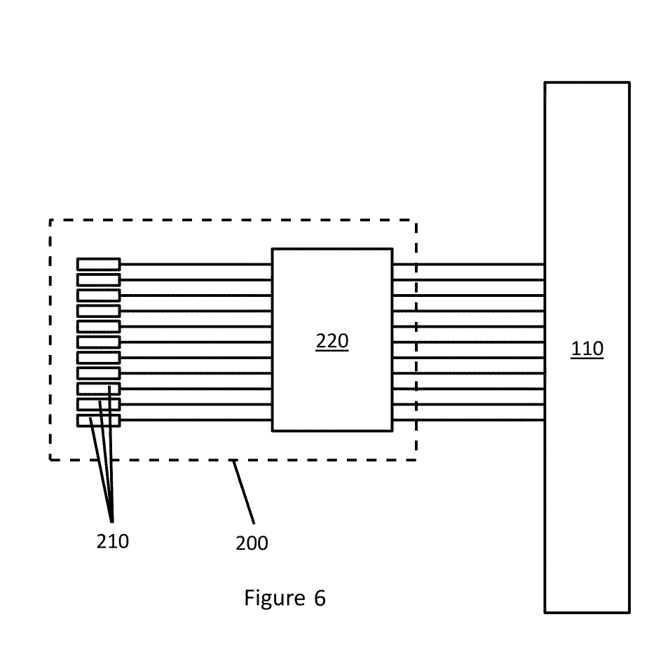

Referring to FIG. 6, an alternative relay state sensor 310 comprises a relay housing 314 having two opposing walls 316 depending from a first planar surface 3121 of a roof 315. The opposing walls define a space to receive a relay 29 of the washing machine 20. In this embodiment, the distance between the walls is substantially the same as the width or length of the relay to be received; however, the walls are provided with tabs 319 at their distal ends to be received underneath the relay, such that the relay is held in place between the walls in a “snap fit” arrangement.

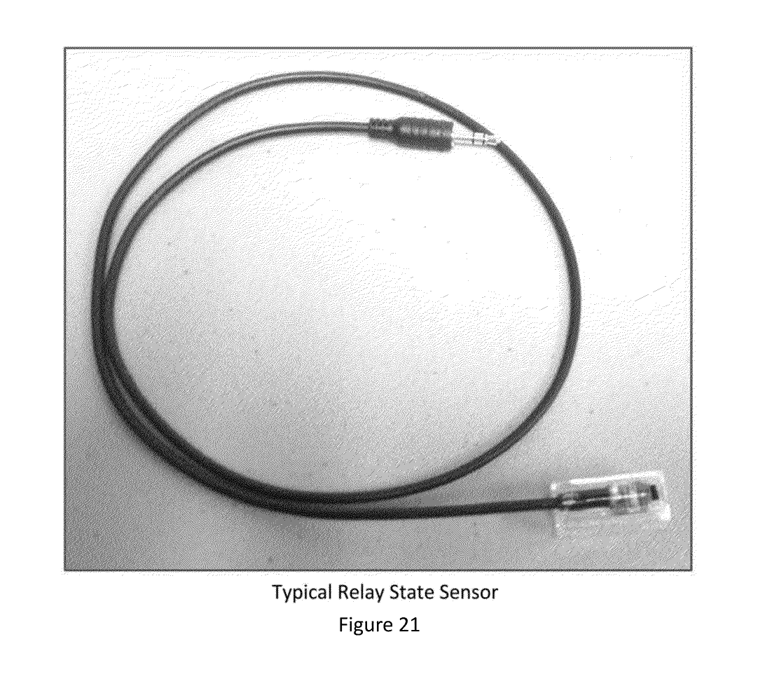

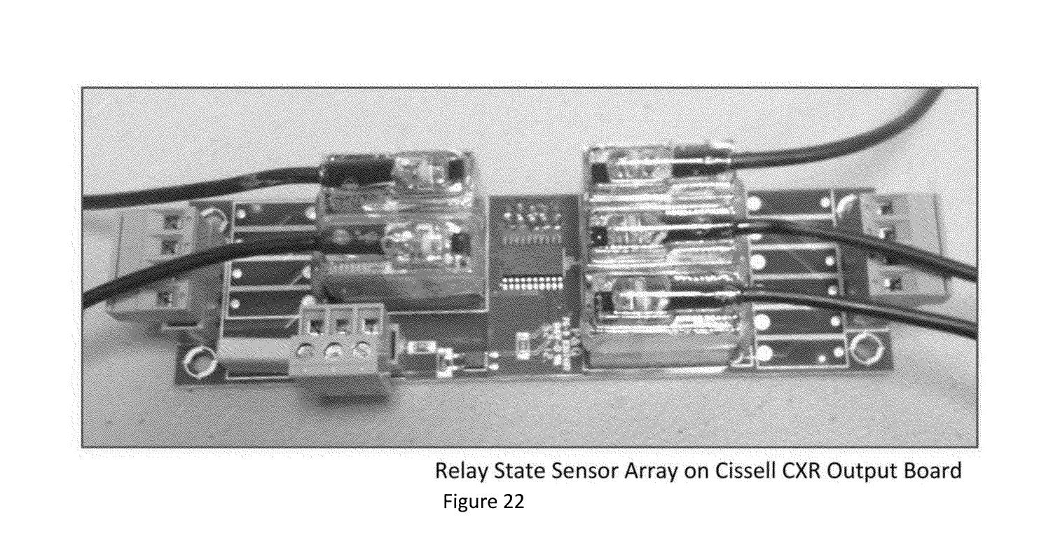

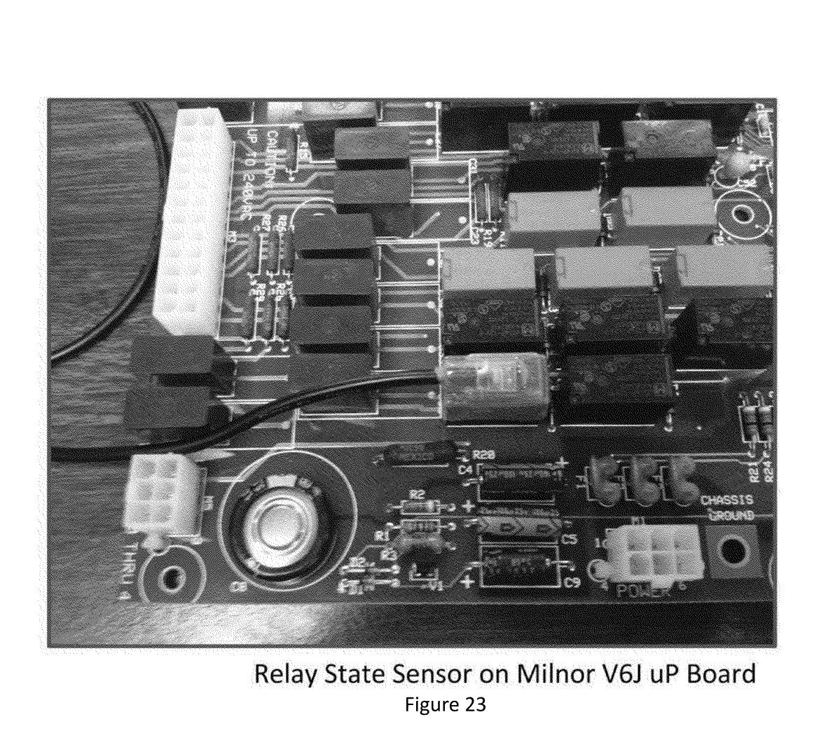

FIGS. 21, 22 and 23 are images of relay state sensors according to a further embodiment of the invention.

Referring to FIGS. 7A-B, the relay state sensors 210 are arranged in an array either secured on a backing board or connected to neighboring sensors 210 at the relay housings. The arrangement of sensors is planar and corresponds to the locations of the relays 29 of the I/O board 26 of the washing machine 20.

The arrangement of the sensors 210 in a corresponding pattern to the relays 29 of the I/O board 26 enables quick and easy connection of the sensor array to the I/O board 26.

A hub 220 is provided with inputs for connection of up to eleven relay state sensor outputs 2121 and a terminal block (not shown) for output of the relay state sensor signals to the interface 110 via a wired connection. The hub also comprises an input for a 5V power supply from the interface 100 for powering of the magnetic field sensors 212.

Various modifications will be apparent to those skilled in the art. For example, it is envisaged that the one or more sensors can include one or more voltage sensors, and the components of the appliance include one or more signal cables configured to pass a signal generated either by the appliance or by a utility meter. The one or more the voltage sensors can include one or more split core or solid core current transformers, each disposed in a housing configured to surround the respective signal cable of the one or more signal cables.

Any number of sensors may be provided and any arrangement of sensors may be provided. The sensors may be exclusively magnetic field sensors or exclusively voltage sensors or alternatively the sensors may be a mixture of magnetic field sensors and voltage sensors. Alternative or additional sensors may also be provided to monitor other components of an appliance.

The interface may be provided with any number of inputs and the processor of the interface may be configured to forward the data received from the inputs without storing.

Whilst endeavoring in the foregoing specification to draw attention to those features of the invention believed to be of particular importance it should be understood that the Applicant claims protection in respect of any patentable feature or combination of features hereinbefore referred to and/or shown in the drawings whether or not particular emphasis has been placed thereon.

What is claimed is:

1. A data acquisition device for monitoring an appliance, the device being removably attachable to the appliance and comprising:
one or more sensors, each sensor being removably attachable to a component of the appliance for sensing a state of that component; and
an interface configured, when the apparatus is attached to the appliance, to receive, process and transmit data indicative of the operation of the appliance, the interface including:
one or more sensor inputs, each configured to receive a signal from a corresponding one of the one or more sensors;
a processor configured to process the signals received from the one or more sensors and generate a data packet containing data indicative of the operation of the appliance based on the received signals; and
a communications module configured to transmit the data packet generated by the processor to a local gateway or remote server.

2. The device of claim 1, wherein the interface further includes:
one or more appliance inputs, each configured to receive a signal generated by the appliance, and wherein the processor is further configured to process the signals generated by the appliance.

3. The device of claim 1, wherein the interface further includes:
one or more utility meter inputs, each configured to receive a signal generated by a utility meter, and wherein the processor is further configured to process the signals generated by the utility meter.

4. The device of claim 1, wherein the one or more sensors include one or more voltage sensors, and the components of the appliance include one or more signal cables configured to pass a signal generated either by the appliance or by a utility meter.

5. The device of claim 1, wherein the one or more sensors include one or more magnetic field sensors, and the components of the appliance include one or more relays configured to control the operation of the appliance, each relay having an active state and an inactive state.

6. The device of claim 5, wherein the one or more relays includes one or more of:
a relay, the state of which is indicative of the start of a cycle of operation of the appliance;
a relay, the state of which is indicative of the end of a cycle of operation of the appliance;
a relay, the state of which is indicative of a call for the supply of a utility from a utility source separate from the appliance, preferably a call for the supply of chemicals from a chemical dispenser;
a relay, the state of which is indicative of the door lock status of the appliance;
a relay, the state of which is indicative of the alarm status of the appliance;
a relay, the state of which is indicative of the lint filter lock status of the appliance; and
a relay, the state of which is indicative of the drain input status of the appliance.

7. The device of claim 2, wherein the signal generated by the appliance is a utility supply signal for controlling the supply of a utility from a utility source separate from the appliance.

8. The device of claim 7, wherein the appliance is a washing machine, the utility source is a chemical dispenser, and the utility supply signal is a chemical pump signal for controlling the supply of chemicals from the chemical dispenser.

9. The device of claim 8, wherein the chemical pump signal is one of a formula select signal and a formula reset signal.

10. The device of claim 3, wherein the utility meter is a water meter, and the signal generated by the water meter is indicative of the volume of cold water and/or hot water to the appliance.

11. The device of claim 3, wherein the utility meter is an electricity meter, and the signal generated by the electricity meter is indicative of the electrical energy delivered to the appliance.

12. The device of claim 1, wherein the interface further comprises a memory, and wherein the processor is further configured to cause the memory to store data pertaining to the received signals for a period of time prior to generating the data packet.

13. The device of claim 12, wherein the appliance is configured to operate according to at least one operating cycle, and wherein the processor is configured to generate the data packet upon determination that the appliance has reached the end of an operating cycle.

14. The device of claim 4, wherein the one or more the voltage sensors include one or more split core or solid core current transformers, each disposed in a housing configured to surround the respective signal cable of the one or more signal cables.

15. The device of claim 5, wherein each of the one or more magnetic field sensors is attached to or embedded within a relay housing sized and shaped for removable attachment to the respective relay of the one or more relays.

16. A relay state sensor device removably attachable to a substantially cuboid-shaped relay for sensing the state of the relay, the sensor device comprising:
a relay housing sized and shaped for removable attachment to the relay;
a magnetic field sensor attached to or embedded within the housing; and
a signal cable electrically coupled at one end to the magnetic field sensor and extending from the housing.

17. The relay state sensor device of claim 16, wherein the relay housing comprises a roof with opposing first and second planar surfaces, and at least two opposing walls depending from the first planar surface of the roof;
wherein, in use, the relay contacts the at least two opposing walls and the first planar surface of the roof;
wherein the magnetic field sensor is attached to or embedded within the second planar surface; and
wherein the signal cable extends from the second planar surface.

18. The relay state sensor device of claim 16, wherein the relay housing comprises four walls depending from the first planar surface of the roof.

19. The relay state sensor device of claim 16, wherein the relay housing forms an open cavity for receiving at least part of a component to be monitored.

20. The relay state sensor device of claim 16, wherein the relay housing is sized and shaped for attachment to the relay with an interference fit.

21. The relay state sensor device of claim 16, wherein the relay housing is sized and shaped for attachment to the relay with a snap fit.

22. The relay state sensor device of claim 16, wherein the housing is formed of silicon.

23. The relay state sensor device of claim 16 further comprising an electrical connector attached to the other end of the signal cable.

24. A relay state sensor array removably attachable to an array of substantially cuboid-shaped relays for sensing the states of the relays, the relay state sensor array comprising a plurality of adjacent relay state sensor devices according to claim 16, each relay state sensor device attached to its neighbor at its housing.

25. An appliance monitoring and reporting system comprising:
one or more data acquisition devices according to claim 1, each data acquisition device removably attached to an appliance; and
a local gateway configured:
to receive and process data packets sent by the communications modules of the one or more data acquisition devices; and
to transmit information indicative of the operation of the corresponding appliances to a remote server, said information based on the received data packets.
